(19) United States
(12) Patent Application Publication
(10) Pub. No.: US 2023/0145576 A1
(43) Pub. Date: May 11, 2023

(54) SEMICONDUCTOR DEVICE

(71) Applicant: ROHM CO., LTD., Kyoto (JP)

(72) Inventor: Shu NAKASHIMA, Kyoto (JP)

(73) Assignee: ROHM CO., LTD., Kyoto (JP)

(21) Appl. No.: 17/983,476

(22) Filed: Nov. 9, 2022

(30) Foreign Application Priority Data
Nov. 10, 2021 (JP) 2021-183047

(51) Int. Cl. H01L 29/78

(52) U.S. Cl. CPC H01L 29/7811

(57) ABSTRACT

A semiconductor device is provided with a semiconductor layer, which includes an active region and an outer peripheral region formed in a frame shape surrounding the active region and having rectangular outer peripheral edges. The outer peripheral region includes: a breakdown voltage structure region in which a breakdown voltage structure is formed; and a specific region extending from the outer peripheral edges of the outer peripheral region to an outer peripheral edge of the breakdown voltage structure region, and formed so that when viewed in a thickness direction of the semiconductor layer, the outer peripheral edge of the breakdown voltage structure region is recessed toward the active region. A contact region is formed on a front surface of the semiconductor layer in the specific region. A wiring electrically connected to the contact region is formed in an outermost peripheral region of the outer peripheral region.

### CROSS-REFERENCE TO RELATED APPLICATION

This application is based upon and claims the benefit of priority from Japanese Patent Application No. 2021-183047, filed on Nov. 10, 2021, the entire contents of which are incorporated herein by reference.

### TECHNICAL FIELD

The present disclosure relates to a semiconductor device.

### BACKGROUND

A semiconductor device having a semiconductor layer that includes an active region in which a transistor is formed and an outer peripheral region surrounding the active region is known. A breakdown voltage structure such as an FLR (Field Limiting Ring) or an EQR (Equipotential Ring) is provided in the peripheral region of the semiconductor device.

However, miniaturization may be required according to a type of semiconductor device. In this regard, there is room for improvement in the outer peripheral region of the semiconductor device.

### SUMMARY

According to one embodiment of the present disclosure, a semiconductor device is provided with a semiconductor layer, which includes an active region and an outer peripheral region formed in a frame shape surrounding the active region and having rectangular outer peripheral edges, wherein the outer peripheral region includes: a breakdown voltage structure region in which a breakdown voltage structure is formed; and a specific region extending from the outer peripheral edges of the outer peripheral region to an outer peripheral edge of the breakdown voltage structure region, and formed so that when viewed in a thickness direction of the semiconductor layer, the outer peripheral edge of the breakdown voltage structure region is recessed toward the active region, wherein a contact region is formed on a front surface of the semiconductor layer in the specific region, and wherein a wiring electrically connected to the contact region is formed in an outermost peripheral region of the outer peripheral region

According to another embodiment of the present disclosure, a semiconductor device is provided with a semiconductor layer, which includes an active region and an outer peripheral region formed in a frame shape surrounding the active region, wherein the outer peripheral region includes four rectangular outer peripheral edges, wherein the outer peripheral region further includes: a breakdown voltage structure region in which a breakdown voltage structure is formed; and a specific region formed between the breakdown voltage structure region and the outer peripheral edges of the outer peripheral region, wherein a contact region is formed on a front surface of the semiconductor layer in the specific region, wherein an outermost peripheral region of the outer peripheral region includes a first outermost peripheral region formed by the specific region, and a second outermost peripheral region in which a wiring electrically connected to the contact region is formed, and wherein the first outermost peripheral region and the second outermost peripheral region each include one or more of the outer peripheral edges that are different from each other.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to a first embodiment.

FIG. 2 is a schematic plan view of the semiconductor device of FIG. 1 and shows a state in which a passivation film is removed.

FIG. 3 is a schematic plan view of a semiconductor layer of the semiconductor device of FIG. 1 and divisionally shows an active region and an outer peripheral region.

FIG. 4 is a schematic cross-sectional view of the semiconductor device taken along line F4-F4 in FIG. 2.

FIG. 5 is a partially enlarged view of a rectangular portion surrounded by a two-dot chain line in FIG. 3.

FIG. 6 is a schematic plan view showing a state in which wirings are added to the semiconductor layer of FIG. 5.

FIG. 7 is a schematic cross-sectional view of the semiconductor device taken along line F7-F7 in FIG. 6.

FIG. 8 is a schematic cross-sectional view of the semiconductor device taken along line F8-F8 in FIG. 6.

FIG. 9 is an enlarged view of a specific region of FIG. 6 and its surroundings.

FIG. 10 is an enlarged schematic plan view showing a corner portion of an outer peripheral region and its surroundings in a semiconductor device of a first comparative example.

FIG. 11 is an enlarged schematic plan view showing a corner portion of an outer peripheral region and its surroundings in a semiconductor device of a second comparative example.

FIG. 12 is a schematic cross-sectional view showing a comparison between the semiconductor device of the second comparative example and the semiconductor device of the present embodiment.

FIG. 13 is a schematic plan view of a semiconductor device of a second embodiment and shows a state in which a passivation film is removed.

FIG. 14 is an enlarged view of a portion of a semiconductor layer of the semiconductor device of FIG. 13 and corresponds to a rectangular portion surrounded by a two-dot chain line in FIG. 13.

FIG. 15 is a schematic plan view showing a state in which wirings are added to the semiconductor layer of FIG. 14.

FIG. 16 is a schematic cross-sectional view of the semiconductor device taken along line F16-F16 in FIG. 15.

FIG. 17 is an enlarged view of a specific region and its surroundings in a semiconductor device according to a modification.

FIG. 18 is an enlarged view of a specific region and its surroundings in a semiconductor device according to a modification.

FIG. 19 is a schematic cross-sectional view of an active region in a semiconductor device according to a modification.

FIG. 20 is an enlarged view of a specific region and its surroundings in a semiconductor device according to a modification.

FIG. 21 is a schematic plan view showing a semiconductor layer of a semiconductor device according to a modification and divisionally shows an active region and an outer peripheral region.

FIG. 22 is an enlarged view of a specific region and its surroundings in a semiconductor device according to a modification.

FIG. 23 is an enlarged view of a specific region and its surroundings in a semiconductor device according to a modification.

FIG. 24 is a schematic plan view showing a semiconductor layer of a semiconductor device according to a modification and divisionally shows an active region and an outer peripheral region.

FIG. 25 is an enlarged view of a specific region and its surroundings in a semiconductor device according to a modification.

FIG. 26 is a schematic plan view showing a semiconductor layer of a semiconductor device according to a modification and divisionally shows an active region and an outer peripheral region.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a semiconductor device of the present disclosure will be described with reference to the accompanying drawings. It should be noted that components shown in the drawings are not necessarily drawn to a constant scale for simplicity and clarity of explanation. In order to facilitate understanding, hatching lines may be omitted in cross-sectional views. The accompanying drawings merely illustrate embodiments of the present disclosure and should not be considered to limit the present disclosure.

The following detailed description includes devices, systems, and methods embodying exemplary embodiments of the present disclosure. This detailed description is merely illustrative in nature and is not intended to limit the embodiments of the present disclosure or the applications and uses of such embodiments.

### First Embodiment

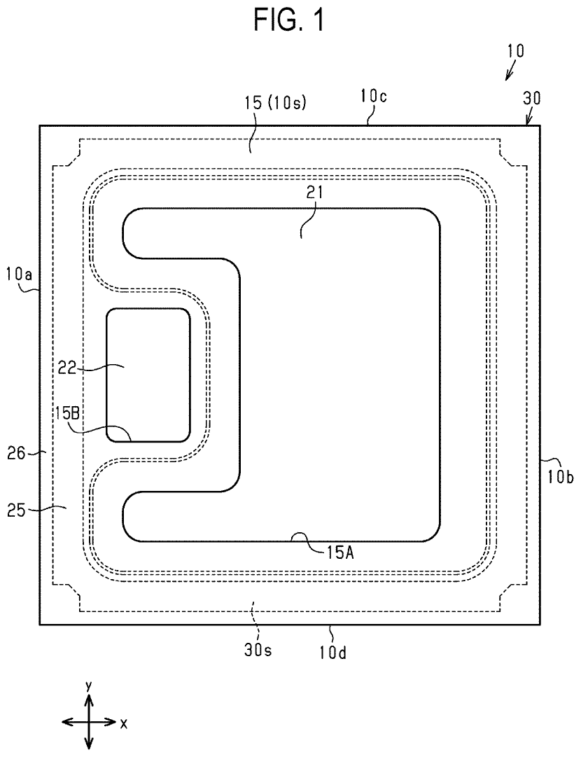

Configuration of a semiconductor device 10 of a first embodiment as a super junction MOSFET (metal oxide semiconductor field effect transistor) will be described with reference to FIGS. 1 to 9.

### (Schematic Configuration of Semiconductor Device)

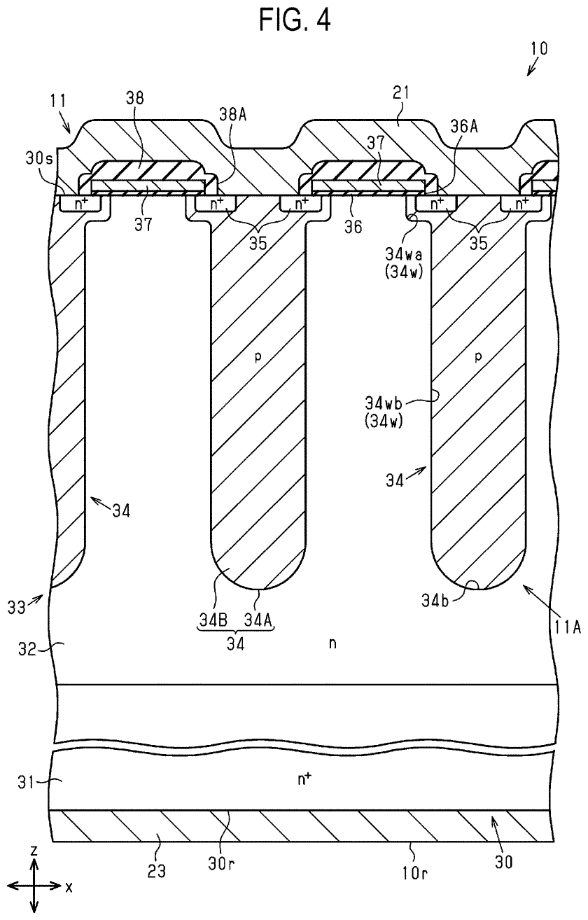

As shown in FIG. 1, the semiconductor device 10 is formed, for example, in a shape of a rectangular flat plate. The semiconductor device 10 has a device front surface 10s, a device rear surface 10r (see FIG. 4) opposite to the device front surface 10s, and four device side surfaces 10a to 10d. The device side surfaces 10a to 10d are surfaces connecting the device front surface 10s and the device rear surface 10r. In the present embodiment, the device side surfaces 10a to 10d are surfaces orthogonal to both the device front surface 10s and the device rear surface 10r. In the present embodiment, the device front surface 10s of the semiconductor device 10 is formed, for example, in a square shape.

In the following description, a direction in which the device front surface 10s and the device rear surface 10r of the semiconductor device 10 are arranged is referred to as “z direction.” It can be said that the z direction is a thickness direction of the semiconductor device 10. Among directions perpendicular to the z direction, two directions perpendicular to each other are defined as “x direction” and “y direction.” In the present embodiment, the device side surfaces 10a and 10b constitute both end surfaces of the semiconductor device 10 in the x direction, and the device side surfaces 10c and 10d constitute both end surfaces of the semiconductor device 10 in the y direction.

The semiconductor device 10 includes a semiconductor layer 30 formed in a rectangular plate shape. Four side surfaces of the semiconductor layer 30 correspond to the device side surfaces 10a to 10d. The semiconductor layer 30 is made of a material containing silicon (Si). The semiconductor layer 30 has a front surface 30s and a rear surface 30r (both of which are shown in FIG. 4). The front surface 30s faces the same side as the device front surface 10s, and the rear surface 30r faces the same side as the device rear surface 10r. Therefore, the front surface 30s and the rear surface 30r are arranged in the z direction. Thus, it can be said that the z direction is a “thickness direction of the semiconductor layer 30.” In addition, “as viewed in the z direction” in the subject specification means “as viewed from the thickness direction of the semiconductor layer 30.”

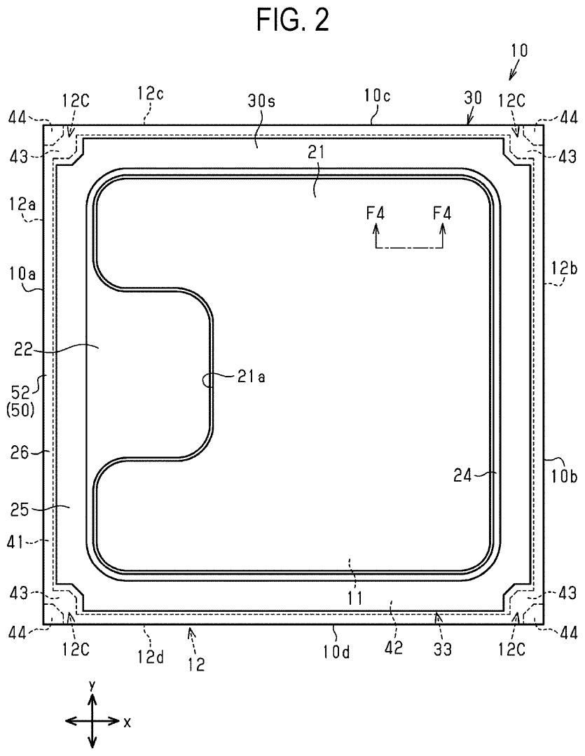

As shown in FIG. 2, the semiconductor device 10 includes a source electrode 21, a gate electrode 22, and a drain electrode 23 (see FIG. 4) as external electrodes for connecting the semiconductor device 10 to the outside. The source electrode 21 and the gate electrode 22 include a common metal film. This metal film is made of, for example, a material containing AlCu (an alloy of aluminum and copper).

The source electrode 21 is an electrode constituting a source of a MOSFET, and is an electrode through which a main current of the semiconductor device 10 flows. The source electrode 21 is formed on the front surface 30s of the semiconductor layer 30. A recess portion 21a recessed toward the device side surface 10b is formed in the source electrode 21 at a location closer to the device side surface 10a than a center in the x direction and at a center in the y direction.

The gate electrode 22 is an electrode constituting a gate of the MOSFET, and is an electrode to which a drive voltage signal for driving the semiconductor device 10 is supplied from the outside of the semiconductor device 10. The gate electrode 22 is formed on the front surface 30s of the semiconductor layer 30. The gate electrode 22 is formed to enter the recess portion 21a of the source electrode 21.

As shown in FIG. 4, the drain electrode 23 is an electrode constituting a drain of the MOSFET, and is an electrode through which the main current of the semiconductor device 10 flows. That is, in the semiconductor device 10, the main current flows from the drain electrode 23 toward the source electrode 21. The drain electrode 23 is formed on the rear surface 30r of the semiconductor layer 30. More specifically, the drain electrode 23 is formed over the entire rear surface 30r of the semiconductor layer 30. Therefore, the drain electrode 23 constitutes the device rear surface 10r.

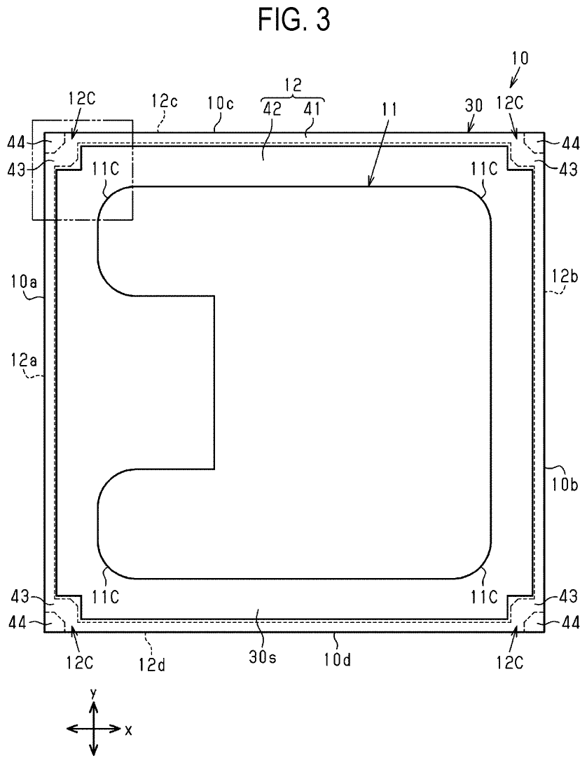

As shown in FIG. 3, the semiconductor layer 30 includes an active region 11 in which a plurality of active cells 11A (see FIG. 4) is formed, and an outer peripheral region 12 provided outside the active region 11 to surround the active region 11. Here, the active cells 11A refer to main cells in which transistors are formed. That is, the active region 11 is a region in which transistors are formed.

Referring to FIGS. 2 and 3 together, the source electrode 21 is provided on the active region 11. The source electrode 21 is formed over most of the active region 11. A shape of the active region 11 viewed from the z direction is a concave shape recessed correspondingly to the recess portion 21a of the source electrode 21. That is, the shape of the active region 11 as viewed in the z direction is similar to a shape of the source electrode 21 as viewed in the z direction. The gate electrode 22 is provided in the recessed portion of the active region 11. In other words, the active cell 11A (see FIG. 4) is not formed directly below the gate electrode 22.

As shown in FIG. 3, in the present embodiment, when viewed in the z direction, four outermost corner portions 11C of the active region 11, which correspond to corner portions constituting four corners of the device front surface 10s, respectively, have a shape including a round portion protruding toward corresponding one of the corner portions of the device front surface 10s.

In addition, the shape of the four outermost corner portions 11C of the active region 11 viewed in the z direction can be changed arbitrarily. In one example, the shape of the four outermost corner portions 11C of the active region 11 viewed in the z direction may be a shape including a chamfered inclined portions. In another example, the shape of the four outermost corner portions 11C of the active region 11 viewed in the z direction may be a step shape.

The outer peripheral region 12 is a region provided with a termination structure for improving a breakdown voltage of the semiconductor device 10. The outer peripheral region 12 is an annular region formed in an outer peripheral portion of the front surface 30s of the semiconductor layer 30. It can be said that the outer peripheral region 12 is a region of the front surface 30s of the semiconductor layer 30 other than the active region 11. The outer peripheral region 12 is rectangular and has first to fourth outer peripheral edges 12a to 12d. The first to fourth outer peripheral edges 12a to 12d of the outer peripheral region 12 correspond to sides of the device front surface 10s defined by the device side surfaces 10a to 10d when viewed in the z direction. The first to fourth outer peripheral edges 12a to 12d constituting the respective sides of the device front surface 10s are formed between the device front surface 10s and the device side surfaces 10a to 10d.

As shown in FIG. 2, the gate electrode 22 is provided in the outer peripheral region 12. A gate finger 24, an FLR (Field Limiting Ring) portion 25, and an equipotential ring (EQR) 26 are further provided in the outer peripheral region 12.

The gate finger 24 is configured to quickly supply the drive voltage signal supplied to the gate electrode 22 even to a portion of the active region 11 spaced apart from the gate electrode 22. The gate finger 24 is connected to the gate electrode 22.

In the present embodiment, the gate finger 24 is provided to surround the source electrode 21 when viewed in the z direction. It can also be said that the gate finger 24 is provided to surround the active region 11 when viewed in the z direction. The gate finger 24 is formed of a material including tungsten (W) or polysilicon. Although one gate finger 24 is illustrated in the present embodiment, a plurality of gate fingers 24 may be provided.

In addition, a shape of the gate finger 24 viewed in the z direction can be changed arbitrarily. In one example, the gate finger 24 may have a shape in which a part of a portion of the gate finger 24 disposed between the source electrode 21 and the device side surface 10b in the x direction is cut off. In other words, the gate finger 24 may have a first end and a second end facing each other with a gap in the y direction at the portion located between the source electrode 21 and the device side surface 10b in the x direction. In this case, the source electrode 21 may also be provided between the first and second ends of the gate finger 24 in the y direction. The semiconductor device 10 may also include a routing wiring portion formed integrally with the source electrode 21 and provided to surround the gate finger 24 and the gate electrode 22.

The FLR portion 25 constitutes the termination structure for improving the breakdown voltage of the semiconductor device 10 and is provided outside the gate finger 24. The FLR portion 25 is formed in a ring shape surrounding the source electrode 21 and the gate electrode 22. The FLR portion 25 has a function of improving the breakdown voltage of the semiconductor device 10 by alleviating an electric field in the outer peripheral region 12 and suppressing influence of external ions.

The equipotential ring 26 constitutes the termination structure for improving the breakdown voltage of the semiconductor device 10 and is formed to surround the FLR portion 25. The equipotential ring 26 is provided on an outermost periphery of the front surface 30s of the semiconductor layer 30.

As shown in FIG. 1, the semiconductor device 10 includes a passivation film 15 configured to cover the source electrode 21, the gate electrode 22, the gate finger 24, the FLR portion 25, and the equipotential ring 26. The passivation film 15 is a protective film that protects the semiconductor device 10 from the outside of the semiconductor device 10. The passivation film 15 is, for example, an organic insulating film made of a material containing polyimide (PI). The passivation film 15 is formed over the entire front surface 30s of the semiconductor layer 30. Therefore, the passivation film 15 constitutes the device front surface 10s.

The passivation film 15 is formed with a first opening 15A that exposes a portion of the source electrode 21 and a second opening 15B that exposes a portion of the gate electrode 22. The portion of the source electrode 21 exposed via the first opening 15A constitutes a source electrode pad. The portion of the gate electrode 22 exposed via the second opening 15B constitutes a gate electrode pad.

### (Configuration of Active Cell)

FIG. 4 shows an example of a cross-sectional structure of a portion of the active region 11. In FIG. 4, hatching lines of some of the components of the semiconductor device 10 in the active region 11 are omitted for the sake of convenience.

As shown in FIG. 4, the semiconductor layer 30 has an n⁺-type drain region 31 formed in a vicinity of the rear surface 30r. The drain region 31 is formed over the entire rear surface 30r of the semiconductor layer 30. That is, the drain region 31 constitutes the rear surface 30r. In the present embodiment, the drain region 31 is composed of an n⁺-type semiconductor substrate. A concentration of n-type impurities in the drain region 31 is, for example, 1×10¹⁸ cm⁻³ or more and 1×10²¹ cm⁻³ or less.

A dimension of the drain region 31 along the z direction (the thickness of the drain region 31) is, for example, 50 μm or more and 400 μm or less. A thickness of the drain region 31 is desirably 100 μm or more.

The drain electrode 23 formed on the rear surface 30r of the semiconductor layer 30 forms an ohmic contact with the drain region 31. The drain electrode 23 is made of a material including at least one selected from the group of a titanium (Ti) layer, a nickel (Ni) layer, a palladium (Pd) layer, a gold (Au) layer, a silver (Ag) layer, and an aluminum (Al) layer.

The drain electrode 23 may have a stack structure in which at least two selected from the group of a Ti layer, a Ni layer, a Pd layer, a Au layer, a Ag layer, and an Al layer are stacked in an arbitrary order. The drain electrode 23 desirably contains a Ti layer as an ohmic electrode. The drain electrode 23 may have a stack structure in which a Ti layer, a Ni layer, a Pd layer, a Au layer, and a Ag layer are stacked in the named order from the rear surface 30r of the semiconductor layer 30.

The semiconductor layer 30 has an n-type drift region 32 formed in a vicinity of the front surface 30s. The drift region 32 is formed over the entire front surface 30s of the semiconductor layer 30. That is, the drift region 32 constitutes the front surface 30s. The drift region 32 is electrically connected to the drain region 31. A boundary between the drain region 31 and the drift region 32 extends parallel to the front surface 30s of the semiconductor layer 30. In the present embodiment, an n-type corresponds to a “first conductivity type,” and a p-type corresponds to a “second conductivity type.”

In the present embodiment, the drift region 32 is formed by an n-type epitaxial layer formed on the semiconductor substrate (drain region 31). A concentration of n-type impurities in the drift region 32 is lower than the n-type impurity concentration in the drain region 31 and is, for example, 1×10¹⁵ cm⁻³ or more and 1×10¹⁷ cm⁻³ or less.

A dimension of the drift region 32 along the z direction (the thickness of the drift region 32) is smaller than the thickness of the drain region 31. A drift region 32 has a thickness of, for example, 10 μm or more and 50 μm or less.

The semiconductor layer 30 has a super junction region 33 (hereinafter, “SJ region 33”) formed in a portion of the drift region 32 in a vicinity of the front surface 30s. In the present embodiment, the SJ region 33 is formed over substantially the entire drift region 32 excluding an outermost peripheral region of the drift region 32 when viewed in the z direction. In this regard, the outermost peripheral region of the drift region 32 is also an outermost peripheral region of the outer peripheral region 12. Therefore, it can be said that the SJ region 33 is formed over the entire active region 11 and substantially the entire outer peripheral region 12 excluding the outermost peripheral region of the outer peripheral region 12.

A plurality of column regions 34 are provided in the SJ region 33. Each column region 34 is formed by filling a column trench 34A extending from the front surface 30s of the semiconductor layer 30 along the z direction with p-type polysilicon 34B. In addition, although the semiconductor device 10 of the present embodiment has a structure in which the SJ region 33 is formed in the semiconductor layer 30, the present disclosure is not limited thereto. The semiconductor device 10 may have, for example, a structure in which a trench type MOSFET structure is formed in the semiconductor layer 30.

The column trench 34A has sidewalls 34w and a bottom wall 34b. In the present embodiment, the sidewalls 34w include a first sidewall 34wa formed close to the front surface 30s of the semiconductor layer 30, and a second sidewall 34wb formed closer to the rear surface 30r of the semiconductor layer 30 than the first sidewall 34wa. The column trench 34A corresponding to the first sidewall 34wa is shallower than the column trench 34A corresponding to the second sidewall 34wb. The first sidewall 34wa is formed to protrude from the second sidewall 34wb in a direction orthogonal to a depth direction of the column trench 34A (the z direction).

In the present embodiment, the bottom wall 34b of the column trench 34A is formed in a curved shape that protrudes toward the rear surface 30r of the semiconductor layer 30. The shape of the bottom wall 34b of the column trench 34A can be changed arbitrarily.

A depth of the column trench 34A is smaller than a thickness of drift region 32. That is, the bottom wall 34b of the column trench 34A is provided closer to the front surface 30s of the semiconductor layer 30 than a boundary between the drift region 32 and the drain region 31. A dimension of the column trench 34A along the z direction (the depth of the column trench 34A) is, for example, 10 μm or more and 40 μm or less. The depth of the column trench 34A is desirably 10 μm or more and 20 μm or less.

The polysilicon 34B is formed such that a surface of the polysilicon 34B exposed from the semiconductor layer 30 is continuous with the front surface 30s of the semiconductor layer 30. In the present embodiment, the surface of the polysilicon 34B is flush with the front surface 30s of the semiconductor layer 30. A concentration of p-type impurities in the polysilicon 34B is, for example, 1×10¹⁵ cm⁻³ or more and 1×10¹⁸ cm⁻³ or less.

An n⁺-type source region 35 is formed in a portion of the polysilicon 34B corresponding to the first sidewall 34wa, i.e., a portion of the polysilicon 34B in a vicinity of the front surface 30s of the semiconductor layer 30. A concentration of n-type impurities in the source region 35 is higher than the n-type impurity concentration in the drift region 32 and is, for example, 1×10¹⁹ cm⁻³ or more and 1×10²⁰ cm⁻³ or less.

A gate insulating film 36 is provided on the front surface 30s of the semiconductor layer 30. The gate insulating film 36 is formed with an opening 36A exposing a portion of the source region 35 and a portion of the polysilicon 34B. For example, a silicon oxide film, a silicon nitride film, an alumina film, a tantalum oxide film, or the like may be used for the gate insulating film 36.

A gate layer 37 is formed on the gate insulating film 36. The gate layer 37 is a layer electrically connected to the gate electrode 22 (see FIG. 2) and is formed of, for example, polysilicon. In addition, the gate layer 37 may be made of the same material as the gate electrode 22.

An interlayer insulating film 38 is provided on the front surface 30s of the semiconductor layer 30 and covers the gate insulating film 36 and the gate layer 37. For example, a silicon oxide film, a silicon nitride film, a tetraethoxysilane (TEOS) film, or the like may be used as the interlayer insulating film 38. A portion of the interlayer insulating film 38 enters the opening 36A of the gate insulating film 36. An opening 38A is formed in the interlayer insulating film 38 to expose a portion of the source region 35 and a portion of the polysilicon 34B.

A source electrode 21 is formed on the interlayer insulating film 38. The source electrode 21 enters the opening 38A of the interlayer insulating film 38. That is, the source electrode 21 is in contact with both the source region 35 and the polysilicon 34B. Although not shown in FIG. 4, the passivation film 15 (see FIG. 1) is provided on the source electrode 21.

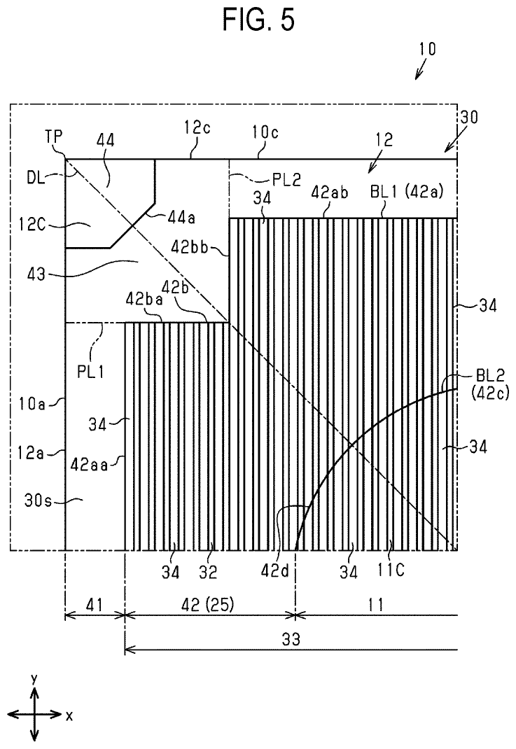

As shown in FIG. 5, according to the present embodiment, in the SJ region 33, the plurality of column regions 34 is formed in a stripe shape to extend along the y direction when viewed in the z direction. Thus, the SJ region 33 is formed by alternately arranging the drift regions 32 and the column regions 34 in the x direction when viewed in the z direction. In the present embodiment, the y direction corresponds to “a direction along a first side of the outer peripheral region.”

The direction in which the plurality of column regions 34 having a stripe shape extends can be changed arbitrarily. In one example, the plurality of column regions 34 may be formed in a stripe shape to extend in the x direction when viewed in the z direction. In this case, the SJ region 33 is formed by alternately arranging the drift regions 32 and the column regions 34 in the y direction when viewed in the z direction. In this case, the x direction corresponds to “a direction along a first side of the outer peripheral region.”

FIG. 5 shows the column region 34 for the sake of convenience, but does not show the gate electrode 22, the source electrode 21, and the like. A size of each column region 34 is also shown schematically, and does not represent an actual size of the plurality of column regions 34.

### (Detailed Configuration of Outer Peripheral Region)

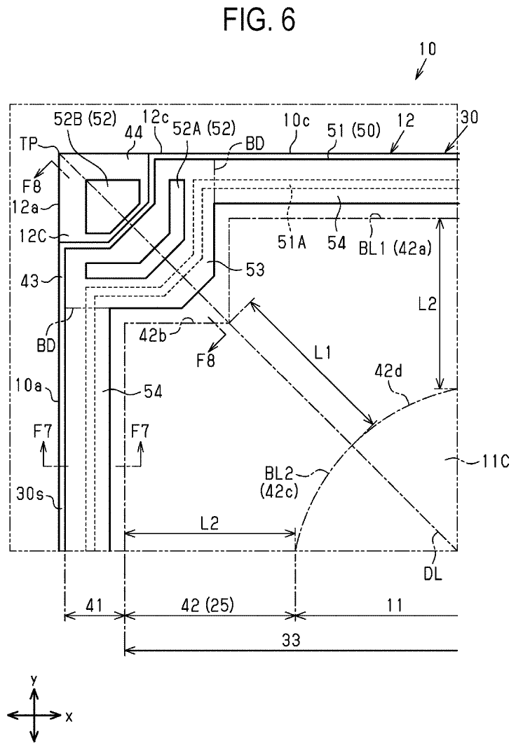

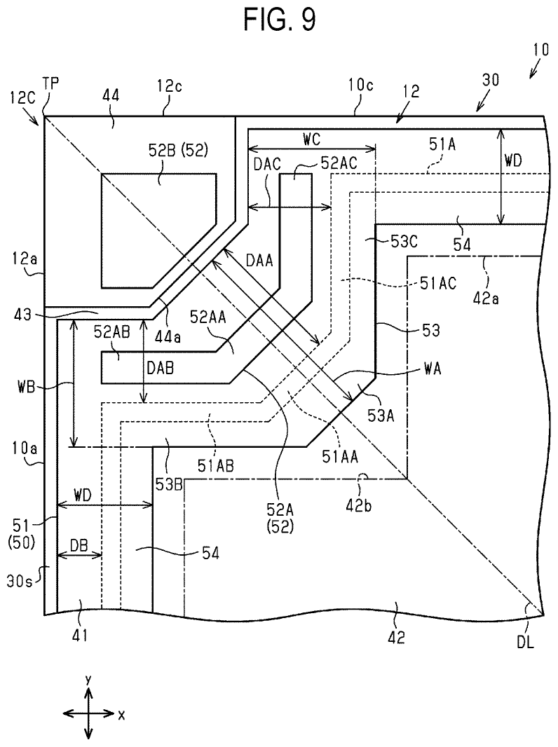

A detailed configuration of the outer peripheral region 12 will be described with reference to FIGS. 5 to 9. FIG. 5 is a plan view schematically showing the front surface 30s of the semiconductor layer 30. FIG. 6 is a schematic plan view showing a state in which an inner wiring 51 and a first outer contact portion 52A and a second outer contact portion 52B of an outer wiring 52, which will be described later, are formed on the front surface 30s of the semiconductor layer 30. FIGS. 6 and 9 omit the plurality of column regions 34 for the sake of convenience.

As shown in FIG. 5, the semiconductor device 10 has a non-column region 41 in the outermost peripheral portion of the outer peripheral region 12 (the outermost peripheral region of the drift region 32). The non-column region 41 is a region surrounding the SJ region 33 when viewed in the z direction, and is a region in which the column regions 34 are not formed with respect to the SJ region 33 in which the column regions 34 are formed. That is, the outer peripheral region 12 has the SJ region 33 and the non-column region 41. The SJ region 33 in the outer peripheral region 12 is a breakdown voltage structure region 42 in which a breakdown voltage structure is formed. In FIG. 5, for the sake of convenience, a boundary between the non-column region 41 and the breakdown voltage structure region 42 is indicated by a boundary line BL1, and a boundary between the breakdown voltage structure region 42 and the active region 11 is indicated by a boundary line BL2.

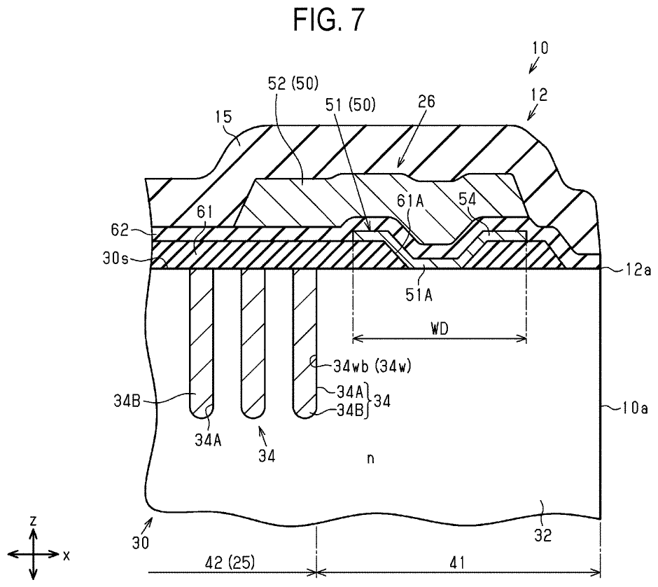

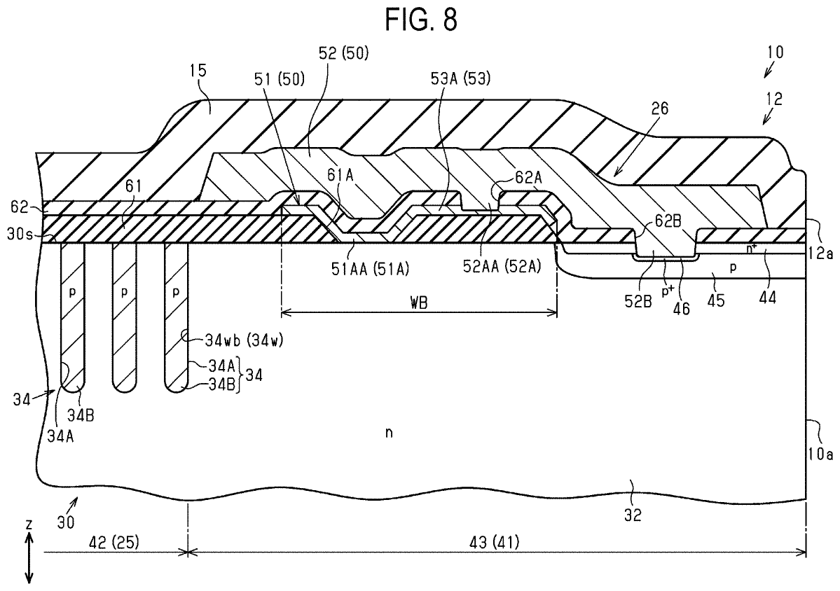

The breakdown voltage structure region 42 is a region corresponding to an inner peripheral portion of the outer peripheral region 12 and surrounding the active region 11. The breakdown voltage structure region 42 is a region in which the drift regions 32 and the column regions 34 are alternately arranged. Each column region 34 in the breakdown voltage structure region 42 does not have the source region 35 formed therein, unlike each column region 34 in the active cell 11A shown in FIG. 4. Therefore, as shown in FIGS. 7 and 8, the sidewall 34w of the column trench 34A in the breakdown voltage structure region 42 is configured by the second sidewall 34wb.

As shown in FIG. 5, the breakdown voltage structure region 42 is a region where the FLR portion 25 (see FIG. 2) is formed. That is, it can be said that the FLR portion 25 has a structure in which the drift regions 32 and the column regions 34 are alternately arranged.

The breakdown voltage structure region 42 has a recess portion 42b formed by recessing an outer peripheral edge 42a of the breakdown voltage structure region 42 toward the active region 11 when viewed in the z direction. In this regard, the outer peripheral edge 42a of the breakdown voltage structure region 42 is a boundary between the breakdown voltage structure region 42 and the non-column region 41, and can be defined by the boundary line BL1. Therefore, the outer peripheral edge 42a (boundary line BL1) of the breakdown voltage structure region 42 can be defined by the outermost column region 34 in the breakdown voltage structure region 42. It can also be said that the outer peripheral edge 42a of the breakdown voltage structure region 42 is an outer peripheral edge of the SJ region 33.

In the present embodiment, the recess portion 42b is formed in each of the corner portions 12C of the outer peripheral region 12. Here, the corner portions 12C of the outer peripheral region 12 refers to the corner portions corresponding to the four corners of the front surface 30s of the semiconductor layer 30 when viewed in the z direction.

In the example shown in FIG. 5, the recess portion 42b is formed by recessing one side 42aa of the outer peripheral edge 42a of the breakdown voltage structure region 42, which extends along the device side surface 10a, toward the device side surface 10b (see FIG. 3), and recessing one side 42ab of the outer peripheral edge 42a of the breakdown voltage structure region 42, which extends along the device side surface 10c, toward the device side surface 10d (see FIG. 3). That is, the recess portion 42b has a shape obtained by cutting out a corner portion of the outer peripheral edge 42a of the breakdown voltage structure region 42, which corresponds to each of the corner portions 12C of the outer peripheral region 12, in a rectangular shape. In the present embodiment, the recess portion 42b is defined by a straight line 42ba extending along the device side surface 10c and a straight line 42bb extending along the device side surface 10a. Thus, an outer peripheral shape of the breakdown voltage structure region 42 is a rectangular frame shape in which the portions corresponding to the four corner portions 12C are cut out.

An inner peripheral edge 42c of the breakdown voltage structure region 42 has a shape conforming to an outer frame shape of the active region 11. In other words, the inner peripheral edge 42c of the breakdown voltage structure region 42 has a substantially rectangular frame shape having a curved portion 42d bulging toward each of the corner portions 12C of the outer peripheral region 12. In this regard, the inner peripheral edge 42c of the breakdown voltage structure region 42 is a boundary between the breakdown voltage structure region 42 and the active region 11, and can be defined by the boundary line BL2. In the present embodiment, a portion of the inner peripheral edge 42c of the breakdown voltage structure region 42, which corresponds to each of the corner portions 12C of the outer peripheral region 12, corresponds to each of the outermost corner portions 11C of the active region 11.

The shape of the inner peripheral edge 42c of the breakdown voltage structure region 42 can be changed arbitrarily. In one example, the portion of the inner peripheral edge 42c of the breakdown voltage structure region 42, which corresponds to each of the corner portions 12C of the outer peripheral region 12, may have a chamfered inclined portion instead of the curved portion 42d. In another example, the portion of the inner peripheral edge 42c of the breakdown voltage structure region 42, which corresponds to each of the corner portions 12C of the outer peripheral region 12, may have a stair-shaped step portion instead of the curved portion 42d.

As shown in FIG. 6, in the present embodiment, a length L1 of the breakdown voltage structure region 42 along a diagonal line DL of the outer peripheral region 12 is longer than a length L2 of the breakdown voltage structure region 42 in a direction perpendicular to one side of the outer peripheral region 12 along which the outer peripheral region 12 extends (a width dimension of the breakdown voltage structure region 42). Here, the diagonal line DL of the outer peripheral region 12 is a straight line that passes through a vertex TP of the first to fourth outer peripheral edges 12a to 12d of the rectangular outer peripheral region 12 and a point on the outer peripheral edge of the active region 11 (the inner peripheral edge 42c of the breakdown voltage structure region 42) shortest from the vertex TP. The diagonal line DL refers to, for example, a straight line passing through the vertex TP of the outer peripheral edge of the rectangular outer peripheral region 12 and forming an angle of 45 degrees with one side of the outer peripheral region 12. In the present embodiment, it can be said that the diagonal line DL of the outer peripheral region 12 is a diagonal line of the semiconductor layer 30 having a square shape when viewed in the z direction. In the example shown in FIG. 6, the diagonal line DL is a straight line connecting an intersection of the first outer peripheral edge 12a and the third outer peripheral edge 12c and an intersection of the second outer peripheral edge 12b and the fourth outer peripheral edge 12d (see FIG. 3). In the present embodiment, directions perpendicular to the first to fourth outer edges 12a to 12d of the outer peripheral region 12, respectively, are the x direction or the y direction.

Both the recess portion 42b and the curved portion 42d are formed on the diagonal line DL of the outer peripheral region 12 in the breakdown voltage structure region 42. Therefore, it can be said that the length L1 of the breakdown voltage structure region 42 is a distance between the curved portion 42d and the recess portion 42b on the diagonal line DL.

The non-column region 41 is a region where the equipotential ring 26 (see FIG. 2) is formed. The non-column region 41 is a region including the first to fourth outer peripheral edges 12a to 12d (see FIG. 3) of the outer peripheral region 12. It can be said that the non-column region 41 constitutes the outermost peripheral region of the outer peripheral region 12. The non-column region 41 is formed to enter the recess portion 42b of the breakdown voltage structure region 42.

The non-column region 41 includes specific regions 43. Each specific region 43 is a region in which the column region 34 is not formed and the drift region 32 is formed. The specific region 43 includes a region that enters the recess portion 42b of the breakdown voltage structure region 42. That is, the specific region 43 is a region extending from the first to fourth outer peripheral edges 12a to 12d of the outer peripheral region 12 to the outer peripheral edge of the breakdown voltage structure region 42, and is a region in which the outer peripheral edge 42a of the breakdown voltage structure region 42 is recessed toward the active region 11 when viewed in the z direction. It can also be said that the specific region 43 is a region in the non-column region 41 recessed from the outer peripheral edge 42a of the breakdown voltage structure region 42. In the present embodiment, the specific region 43 is formed in each of the corner portions 12C of the outer peripheral region 12. In other words, a plurality of (four, in the present embodiment) specific regions 43 are formed. In FIG. 5, the specific region 43 is defined by a two-dot chain line within the semiconductor layer 30. More specifically, the specific region 43 shown in FIG. 5 is a region which is surrounded by a straight line PL1 as a two-dot chain line extending along the third outer peripheral edge 12c from the straight line 42ba of the recess portion 42b of the breakdown voltage structure region 42 to the first outer peripheral edge 12a, a straight line PL2 as a two-dot chain line extending along the first outer peripheral edge 12a from the straight line 42bb of the recess portion 42b to the third outer peripheral edge 12c, the straight line 42ba, the straight line 42bb, the first outer peripheral edge 12a, and the third outer peripheral edge 12c.

As shown in FIGS. 5, 6, and 8, the non-column region 41 is provided with an n⁺-type contact region 44. The contact region 44 is a region electrically connected to the drain electrode 23 and is a region for stabilizing a potential of the drift region 32. A concentration of n-type impurities in the contact region 44 is higher than the n-type impurity concentration in the drift region 32 and is, for example, 1×10¹⁸ cm⁻³ or more and 1×10²¹ cm⁻³ or less.

In the present embodiment, the contact region 44 is formed in the specific region 43. It can be said that the contact region 44 is formed in each of the corner portions 12C of the outer peripheral region 12. As shown in FIG. 5, when viewed in the z direction, the contact region 44 has a substantially rectangular shape in which a portion of the contact region 44 adjacent to the breakdown voltage structure region 42 in a direction extending along the diagonal line DL has a chamfered inclined portion 44a. Thus, the contact region 44 is formed in the non-column region 41 at a location corresponding to each of the corner portions 12C. That is, the contact region 44 is not formed annularly to surround the breakdown voltage structure region 42. The contact region 44 is formed to be spaced apart from the breakdown voltage structure region 42 in the direction extending along the diagonal line DL. As shown in FIG. 8, the contact region 44 is formed on the front surface 30s of the semiconductor layer 30. Thus, it can be said that the contact region 44 is formed on the front surface 30s of the semiconductor layer 30 within the specific region 43.

As shown in FIG. 8, the semiconductor layer 30 includes a p-type first well region 45 covering the contact region 44 and a p⁺-type second well region 46 formed in the first well region 45 on a side of the contact region 44. The second well region 46 is formed in a portion of the first well region 45. Both the first well region 45 and the second well region 46 are formed in the specific region 43. Just like the contact region 44, the first well region 45 is formed in the non-column region 41 at a location corresponding to each of the corner portions 12C (see FIG. 5). The first well region 45 is not formed in a ring shape surrounding the active region 11 (see FIG. 5), but is spaced apart from the breakdown voltage structure region 42 in the direction extending along the diagonal line DL (see FIG. 5).

A concentration of p-type impurities in the second well region 46 is higher than a concentration of p-type impurities in the first well region 45. The p-type impurity concentration in the first well region 45 is, for example, 1×10¹⁵ cm⁻³ or more and 1×10¹⁸ cm⁻³ or less. The p-type impurity concentration in the second well region 46 is, for example, 1×10¹⁸ cm⁻³ or more and 1×10²¹ cm⁻³ or less.

As shown in FIGS. 6 to 8, the equipotential ring 26 is provided in the non-column region 41. As shown in FIG. 8, the equipotential ring 26 is electrically connected to the contact region 44.

As shown in FIGS. 7 and 8, the equipotential ring 26 has a wiring 50 electrically connected to the contact region 44. The wiring 50 is formed in the outer peripheral region 12. As shown in FIG. 2, the wiring 50 is formed in a ring shape surrounding the active region 11.

As shown in FIGS. 7 and 8, the wiring 50 includes an inner wiring 51 and an outer wiring 52 electrically connected to both the inner wiring 51 and the contact region 44. The inner wiring 51 is positioned in the non-column region 41 when viewed in the z direction. The inner wiring 51 is formed on an insulating film 61 covering a region of the front surface 30s of the semiconductor layer 30 corresponding to the outer peripheral region 12. The insulating film 61 is an oxide film and is formed of, for example, a silicon oxide film (SiO₂ film). An opening 61A is provided in the insulating film 61 at a portion (non-column region 41) outward of the breakdown voltage structure region 42. In the present embodiment, an outer peripheral edge of the insulating film 61 is formed at the same position as an inner peripheral edge of the contact region 44 when viewed in the z direction. Therefore, the insulating film 61 does not cover the contact region 44.

The inner wiring 51 is mainly provided in the opening 61A and a region outward of the opening 61A. The inner wiring 51 is provided to cover an outer peripheral edge portion of the insulating film 61. In the present embodiment, an outer peripheral edge of the inner wiring 51 is formed adjacent to an inner peripheral edge of the contact region 44 when viewed in the z direction.

As shown in FIGS. 3 and 6, the inner wiring 51 is formed in a ring shape surrounding the breakdown voltage structure region 42. An inner peripheral edge of the inner wiring 51 is provided outward of the breakdown voltage structure region 42 with a gap left therebetween. As shown in FIG. 6, the inner wiring 51 is provided to enter the recess portion 42b of the breakdown voltage structure region 42. The inner wiring 51 is positioned inward of the contact region 44 in the specific region 43, and is positioned at the outermost periphery of the outer peripheral region 12 in a region other than the specific region 43.

A portion of the inner wiring 51 corresponding to the specific region 43 is defined as a surrounding wiring portion 53, and a portion of the inner wiring 51 corresponding to the region other than the specific region 43 is defined as an outermost peripheral wiring portion 54. The surrounding wiring portion 53 is a wiring that connects ends of the adjacent outermost peripheral wiring portions 54 to each other, and is a wiring that enters the recess portion 42b of the breakdown voltage structure region 42. The outermost peripheral wiring portion 54 is a wiring formed in the outermost peripheral region (non-column region 41) of the outer peripheral region 12, and is a wiring portion of the inner wiring 51 extending along the first to fourth outer peripheral edges 12a to 12d. The outermost peripheral wiring portion 54 is formed at a position adjacent to the first to fourth outer peripheral edges 12a to 12d when viewed in the z direction. In other words, the outermost peripheral wiring portion 54 is positioned at the outermost periphery of the outer peripheral region 12. In FIG. 6, for the sake of convenience, a boundary BD between the surrounding wiring portion 53 and the outermost peripheral wiring portion 54 is indicated by a two-dot chain line.

FIG. 9 is an enlarged view of the surrounding wiring portion 53 and its surroundings in FIG. 6. As shown in FIG. 9, the surrounding wiring portion 53 is formed to surround the contact region 44 when viewed in the z direction. When viewed in the z direction, the surrounding wiring portion 53 includes a first portion 53A extending in a direction orthogonal to the diagonal line DL, a second portion 53B extending along the x direction, and a third portion 53C extending along the y direction.

The first portion 53A is provided at a position adjacent to the inclined portion 44a of the contact region 44 in the direction extending along the diagonal line DL. When viewed in the z direction, the first portion 53A extends along the direction in which the inclined portion 44a extends.

The first portion 53A is provided between the second portion 53B and the third portion 53C. In the illustrated example, the second portion 53B is positioned closer to the first outer peripheral edge 12a than the first portion 53A, and connects the first portion 53A and the outermost peripheral wiring portion 54 to each other. The third portion 53C is positioned closer to the third outer peripheral edge 12c than the first portion 53A, and connects the first portion 53A and the outermost peripheral wiring portion 54 to each other.

A width dimension WA of the first portion 53A of the surrounding wiring portion 53 is larger than both a width dimension WB of the second portion 53B and a width dimension WC of the third portion 53C. In this regard, the width dimension WA of the first portion 53A can be defined by a dimension of the first portion 53A on the diagonal line DL. The width dimension WB of the second portion 53B can be defined by a dimension of the second portion 53B in the y direction. The width dimension WC of the third portion 53C can be defined by a dimension of the third portion 53C in the x direction.

The width dimension WA of the first portion 53A is larger than a width dimension WD of the outermost peripheral wiring portion 54. Both the width dimension WB of the second portion 53B and the width dimension WC of the third portion 53C are larger than the width dimension WD of the outermost peripheral wiring portion 54. In this regard, the width dimension WD of the outermost peripheral wiring portion 54 can be defined by a dimension in a direction orthogonal to a direction in which the outermost peripheral wiring portion 54 extends when viewed in the z direction.

As shown in FIG. 6, the inner wiring 51 includes an inner contact portion 51A connected to the semiconductor layer 30. More specifically, the inner contact portion 51A is in contact with the drift region 32 via the opening 61A. The inner wiring 51 is formed of, for example, polysilicon.

The inner contact portion 51A is formed closer to the breakdown voltage structure region 42 than a center of the inner wiring 51 in a width direction of the inner wiring 51. In this regard, the width direction of the inner wiring 51 can be defined by a direction orthogonal to a direction in which the inner wiring 51 extends annularly when viewed in the z direction. The inner contact portion 51A is formed in an annular shape surrounding the breakdown voltage structure region 42.

As shown in FIG. 9, the inner contact portion 51A in the surrounding wiring portion 53 includes a first portion 51AA extending in a direction in which the first portion 53A of the surrounding wiring portion 53 extends (a direction orthogonal to the diagonal line DL when viewed in the z direction), a second portion 51AB extending in the x direction, and a third portion 51AC extending in the y direction.

The first portion 51AA is provided at a position overlapping with the first portion 53A of the surrounding wiring portion 53 when viewed in the z direction. The first portion 51AA is provided to straddle the diagonal line DL when viewed in the z direction. The second portion 51AB is provided at both a position overlapping with the first portion 53A of the surrounding wiring portion 53 and a position overlapping with the second portion 53B of the surrounding wiring portion 53 when viewed in the z direction. The third portion 51AC is provided at both a position overlapping with the first portion 53A of the surrounding wiring portion 53 and a position overlapping with the third portion 53C of the surrounding wiring portion 53 when viewed in the z direction.

A distance DAA between the first portion 51AA and the outer peripheral edge of the first portion 53A of the surrounding wiring portion 53 is longer than a distance DAB between the second portion 51AB and the outer peripheral edge of the second portion 53B of the surrounding wiring portion 53. The distance DAA is longer than a distance DAC between the third portion 51AC and the outer peripheral edge of the third portion 53C of the surrounding wiring portion 53. The distance DAA is longer than a distance DB between the inner contact portion 51A in the outermost peripheral wiring portion 54 and the outer peripheral edge of the outermost peripheral wiring portion 54. In addition, the distance DAB and the distance DAC are longer than the distance DB.

As shown in FIGS. 7 and 8, the outer wiring 52 is formed on an interlayer insulating film 62 covering both the insulating film 61 and the inner wiring 51. The interlayer insulating film 62 is formed integrally with the interlayer insulating film 38 (see FIG. 4) in the active region 11. Therefore, the interlayer insulating film 62 is made of the same material as the interlayer insulating film 38. Further, the interlayer insulating film 62 covers the entire outer peripheral region 12. Thus, the interlayer insulating film 62 covers the contact region 44. In the present embodiment, a thickness of the interlayer insulating film 62 is thinner than a thickness of the insulating film 61. The thickness of the interlayer insulating film 62 and the thickness of the insulating film 61 can be changed arbitrarily. The thickness of the insulating film 61 may be less than or equal to the thickness of the interlayer insulating film 62. The interlayer insulating film 62 is made of, for example, NSG (None-doped Silicate Glass) or BPSG (Boron Phosphorous Silicate Glass). The passivation film 15 is provided on the outer wiring 52. The passivation film 15 covers the entire outer wiring 52.

The outer wiring 52 is formed of, for example, a metal film common to the source electrode 21 and the gate electrode 22 (see FIG. 2). The metal film is made of, for example, a material containing AlCu.

The outer wiring 52 is provided at a position overlapping with the inner wiring 51 when viewed in the z direction. Therefore, the outer wiring 52 is located in the non-column region 41 when viewed in the z direction. A thickness of the outer wiring 52 is larger than a thickness of the inner wiring 51. The thickness of the outer wiring 52 is larger than both the thickness of the insulating film 61 and the thickness of the interlayer insulating film 62.

As shown in FIG. 7, a portion of the outer wiring 52 that covers the outermost peripheral wiring portion 54 is provided to cover the outer peripheral edge 42a (see FIG. 6) of the breakdown voltage structure region 42. On the other hand, as shown in FIG. 8, a portion of the outer wiring 52 that covers the surrounding wiring portion 53 is provided to be located outward of the outer peripheral edge 42a of the breakdown voltage structure region 42. As shown in FIG. 2, the outer wiring 52 is formed to cover the recess portion 42b (see FIG. 6) of the breakdown voltage structure region 42 when viewed in the z direction.

As shown in FIG. 8, the outer wiring 52 includes a first outer contact portion 52A connected to the inner wiring 51 and a second outer contact portion 52B connected to the contact region 44. The first outer contact portion 52A is provided to penetrate the interlayer insulating film 62 in a film thickness direction (z direction). As shown in FIG. 6, the first outer contact portion 52A is provided in the specific region 43. On the other hand, the first outer contact portion 52A is not provided in a region other than the specific region 43. Therefore, the first outer contact portion 52A is not formed in an annular shape surrounding the breakdown voltage structure region 42.

The first outer contact portion 52A is provided at a position overlapping with the surrounding wiring portion 53 when viewed in the z direction. The first outer contact portion 52A is connected to the surrounding wiring portion 53. The first outer contact portion 52A is formed to surround the contact region 44 when viewed in the z direction.

As shown in FIG. 9, the first outer contact portion 52A is provided closer to the contact region 44 than the inner contact portion 51A. It can be said that the first outer contact portion 52A is provided between the inner contact portion 51A and the contact region 44 in the direction extending along the diagonal line DL. Therefore, it can be said that the inner contact portion 51A is provided closer to the outer peripheral edge 42a of the breakdown voltage structure region 42 than the first outer contact portion 52A.

The first outer contact portion 52A includes a first portion 52AA extending in the direction in which the first portion 53A of the surrounding wiring portion 53 extends (the direction orthogonal to the diagonal line DL when viewed in the z direction), a second portion 52AB extending in the x direction, and a third portion 52AC extending in the y direction.

The first portion 52AA is parallel to the first portion 51AA of the inner contact portion 51A when viewed in the z direction. The first portion 52AA is provided between the first portion 51AA of the inner contact portion 51A and the contact region 44 in the direction extending along the diagonal line DL. The first portion 52AA is formed closer to the first portion 51AA of the inner contact portion 51A than the contact region 44 in the direction extending along the diagonal line DL.

The second portion 52AB is provided between the second portion 51AB of the inner contact portion 51A and the contact region 44 in they direction. The second portion 52AB is formed closer to the second portion 51AB of the inner contact portion 51A than the contact region 44 in the y direction.

The third portion 52AC is provided between the third portion 51AC of the inner contact portion 51A and the contact region 44 in the x direction. The third portion 52AC is formed closer to the third portion 51AC of the inner contact portion 51A than the contact region 44 in the x direction.

As shown in FIG. 8, an opening 62A exposing the inner wiring 51 is formed in the interlayer insulating film 62 formed on the inner wiring 51. The first outer contact portion 52A is in contact with the inner wiring 51 via the opening 62A of the interlayer insulating film 62.

The second outer contact portion 52B is provided in the specific region 43. More specifically, the second outer contact portion 52B is provided at a position overlapping with the contact region 44 when viewed in the z direction. As shown in FIG. 9, the second outer contact portion 52B is provided closer to the outer edge of the outer peripheral region 12 than the inner wiring 51. Further, the second outer contact portion 52B is provided closer to the outer edge of the outer peripheral region 12 than the first outer contact portion 52A. It can be said that the first outer contact portion 52A is formed to surround the second outer contact portion 52B when viewed in the z direction.

As shown in FIG. 8, an opening 62B exposing the contact region 44 is formed in the interlayer insulating film 62 formed on the contact region 44. The second outer contact portion 52B is in contact with the contact region 44 via the opening 62B of the interlayer insulating film 62. In the present embodiment, a tip of the second outer contact portion 52B is in contact with the second well region 46 via the contact region 44 in the thickness direction (z direction) of the semiconductor layer 30. A side surface of the second outer contact portion 52B is in contact with the contact region 44.

As shown in FIGS. 6 and 7, neither the first outer contact portion 52A nor the second outer contact portion 52B is provided in a region other than the specific region 43. That is, as shown in FIG. 7, the inner wiring 51 is located at the outermost periphery of the outer peripheral region 12 in the region other than the specific region 43.

### (Operations)

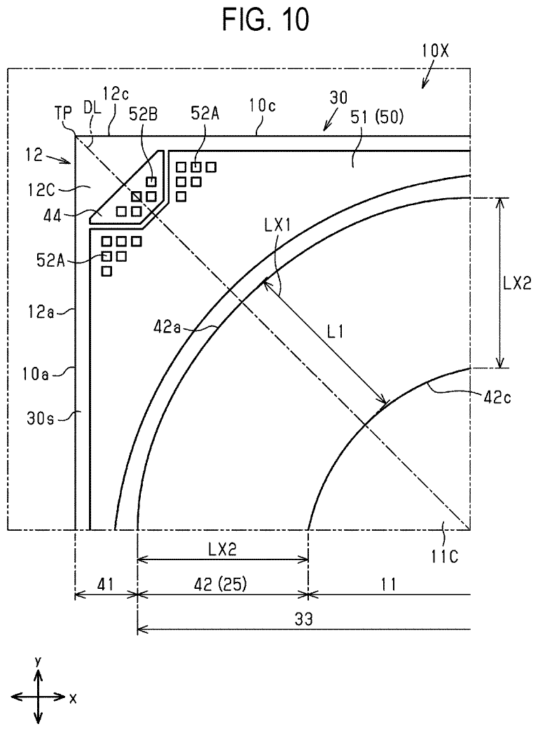

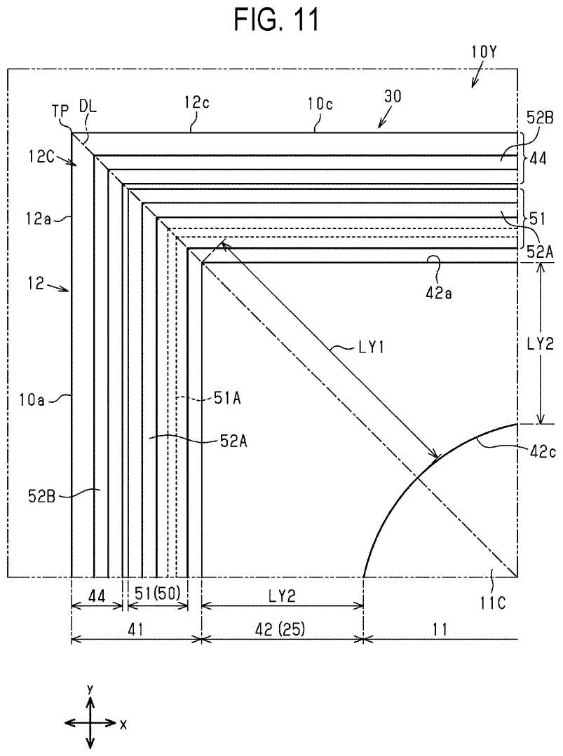

Operations of the present embodiment will be described with reference to FIGS. 6 and 10 to 12. FIG. 10 shows a corner portion of a peripheral region of a semiconductor device 10X according to a first comparative example, and FIG. 11 shows a corner portion of a peripheral region of a semiconductor device 10Y according to a second comparative example. In the following description, the same components of the semiconductor devices 10X and 10Y of the respective comparative examples as the components of the semiconductor device 10 of the first embodiment will be designated by like reference numerals, and the description thereof may be omitted.

As shown in FIG. 10, in the semiconductor device 10X of the first comparative example, the SJ region 33 corresponding to the corner portions 12C of the outer peripheral region 12 is formed in a curved shape protruding in the direction extending along the diagonal line DL. That is, the outer peripheral edge 42a of the breakdown voltage structure region 42 corresponding to the corner portions 12C of the outer peripheral region 12 is formed in a curved shape protruding in the direction extending along the diagonal line DL. Here, when the entire region corresponding to the corner portions 12C of the outer peripheral edge 42a of the breakdown voltage structure region 42 is formed in an arc shape as shown in FIG. 10, a length LX1 of the breakdown voltage structure region 42 along the diagonal line DL is equal to a length LX2 which is a width dimension of the breakdown voltage structure region 42 perpendicular to one side of the outer peripheral region 12.

Here, in the region of the breakdown voltage structure region 42 corresponding to the corner portions 12C of the outer peripheral region 12, the electric field of the semiconductor layer 30 extends in the direction along the diagonal line DL rather than in the x direction or the y direction. Therefore, a depletion layer cannot sufficiently extend in the semiconductor layer 30 with respect to the length LX1 of the breakdown voltage structure region 42 along the diagonal line DL. As a result, a leakage current is generated at a voltage lower than an expected breakdown voltage.

In order to increase a length of the breakdown voltage structure region 42 along the diagonal line DL, as shown in FIG. 11, the region corresponding to the corner portions 12C of the outer peripheral edge 42a of the breakdown voltage structure region 42 is formed in a rectangular shape in the semiconductor device 10Y according to the second comparative example. As a result, a length LY1 of the breakdown voltage structure region 42 along the diagonal line DL is larger than a length LY2 of the breakdown voltage structure region 42 in the direction perpendicular to one side of the outer peripheral region 12 (in the x direction or the y direction).

In the semiconductor device 10Y according to the second comparative example, the inner wiring 51 is provided to surround the breakdown voltage structure region 42 when viewed in the z direction. Furthermore, the contact region 44 is provided to surround the inner wiring 51 when viewed in the z direction. In addition, the first outer contact portion 52A of the outer wiring 52 is formed annularly along the inner wiring 51, and the second outer contact portion 52B is formed annularly along the contact region 44.

As shown in FIG. 11, in the semiconductor device 10Y according to the second comparative example, the inner wiring 51 and the contact region 44 are arranged along the entire circumference of the outer peripheral region 12. Therefore, the semiconductor device 10Y according to the second comparative example becomes larger in size. In addition, since the first outer contact portion 52A is formed along the entire circumference of the outer peripheral region 12, the inner wiring 51 is arranged so that the inner contact portion MA and the first outer contact portion 52A are aligned along the entire circumference of the outer peripheral region 12. Therefore, the inner wiring 51 requires a space for forming the inner contact portion MA and the first outer contact portion 52A over the entire circumference of the outer peripheral region 12. As a result, the outer peripheral region 12 is required to have a large width over the entire circumference of the semiconductor device 10Y, which hinders miniaturization of the semiconductor device 10Y.

In this respect, as shown in FIG. 6, in the semiconductor device 10 according to the present embodiment, the specific region 43 is set in each of the corner portions 12C of the outer peripheral region 12. Therefore, the region for forming the contact region 44 and the respective outer contact portions 52A and 52B can be secured while securing the required lengths L1 and L2 of the breakdown voltage structure region 42. Even when the shape of the specific region 43 viewed in the z direction is rectangular, it is possible to secure the length L1 of the breakdown voltage structure region 42 which is the shortest distance between the recess portion 42b of the outer peripheral edge 42a of the breakdown voltage structure region 42 and the active region 11. Accordingly, it is possible to suppress generation of a leakage current at a voltage lower than the expected breakdown voltage. As described above, the size of the recess portion 42b of the breakdown voltage structure region 42, i.e., the size of the specific region 43, is set such that the length L1 of the breakdown voltage structure region 42 becomes larger than the length L2 of the breakdown voltage structure region 42 and becomes a length capable of suppressing generation of a leak current at a voltage lower than the expected breakdown voltage.

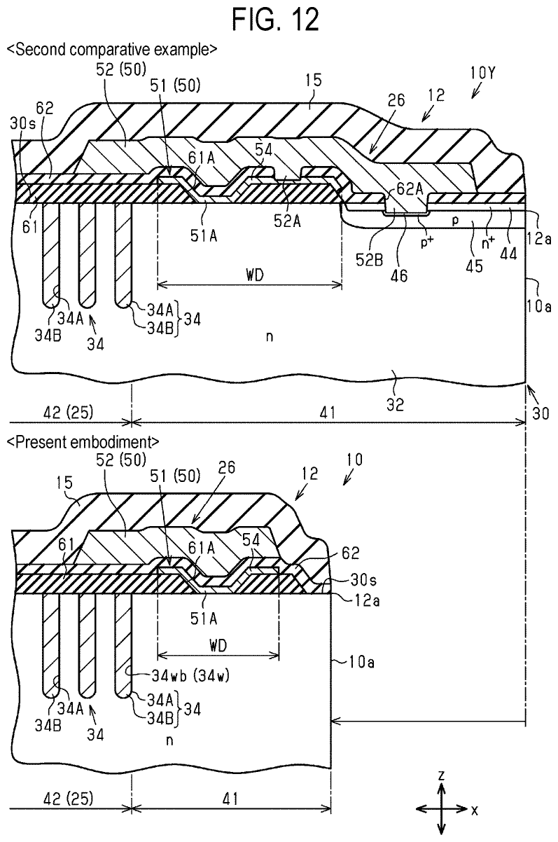

Further, in the semiconductor device 10 according to the present embodiment, the specific region 43 is formed only in the corner portions 12C of the outer peripheral region 12 and is not formed over the entire circumference of the outer peripheral region 12. That is, in the semiconductor device 10 according to of the present embodiment, the contact region 44 formed in the specific region 43 is formed only in the corner portions 12C of the outer peripheral region 12 and is not formed over the entire circumference of the outer peripheral region 12. For this reason, the inner wiring 51 is formed on the outermost periphery of the outer peripheral region 12 in the region other than the corner portions 12C of the outer peripheral region 12. In other words, in the region other than the corner portions 12C of the outer peripheral region 12, the inner wiring 51 is formed at a position adjacent to the first to fourth outer peripheral edges 12a to 12d when viewed in the z direction. Thus, as shown in FIG. 12, in the semiconductor device 10 according to the present embodiment, the non-column region 41 can be made smaller as much as the contact region 44, as compared with the semiconductor device 10Y according to the second comparative example.

In addition, as shown in FIG. 6, in the semiconductor device 10 according to the present embodiment, both the first outer contact portion 52A and the second outer contact portion 52B of the outer wiring 52 formed in the specific region 43 are formed only in the corner portions 12C of the outer peripheral region 12, and is not formed over the entire circumference of the outer peripheral region 12. Thus, as shown in FIG. 12, the width dimension WD of the inner wiring 51 in the region other than the corner portions 12C of the outer peripheral region 12 of the semiconductor device 10 according to the present embodiment is smaller than the width dimension WD of the inner wiring 51 in the region other than the corner portions 12C (see FIG. 11) of the outer peripheral region 12 of the semiconductor device 10Y according to the second comparative example. Therefore, the width dimension of the non-column region 41 can be further reduced. Thus, as shown in FIG. 12, the outer peripheral region 12 of the semiconductor device 10 according to the present embodiment can be made smaller as compared with the semiconductor device 10Y according to the second comparative example.

### (Effects)

According to the semiconductor device 10 of the present embodiment, the following effects are obtained.

(1-1) The semiconductor device 10 is provided with the semiconductor layer 30 that includes the active region 11 and the outer peripheral region 12, which is formed in a frame shape surrounding the active region 11 and having the first to fourth peripheral edges 12a to 12d. The breakdown voltage structure region 42, in which the breakdown voltage structure is formed, and the specific region 43 recessed from the outer peripheral edge 42a of the breakdown voltage structure region 42 are formed in the outer peripheral region 12. The contact region 44 is formed on the front surface 30s of the semiconductor layer 30 within the specific region 43. The wiring 50 electrically connected to the contact region 44 is formed in the non-column region 41 that constitutes the outermost peripheral region of the outer peripheral region 12.

According to the configuration described above, in the non-column region 41, the wiring 50 is formed but the contact region 44 is not formed. As a result, the size of the semiconductor device 10 can be reduced as compared with a configuration in which the contact region 44 is formed over the entire circumference of the outer peripheral region 12.

(1-2) The specific region 43 is formed in the corner portions 12C of the outer peripheral region 12. According to this configuration, in the corner portions 12C of the outer peripheral region 12, the distance between the active region 11 and the first to fourth outer peripheral edges 12a to 12d (the device side surfaces 10a to 10d) in the semiconductor layer 30 becomes large. Therefore, even when the specific region 43 is formed in the corner portions 12C, it is possible to secure the length L1 of the breakdown voltage structure region 42 on the diagonal line DL of the outer peripheral region 12. Accordingly, it is possible to suppress generation of a leakage current at a voltage lower than the expected breakdown voltage.

(1-3) The length L1 of the breakdown voltage structure region 42 on the diagonal line DL of the outer peripheral region 12 is larger than the length L2 of the breakdown voltage structure region 42 in the direction perpendicular to one side of the outer peripheral region 12. According to this configuration, by increasing the length L1 of the breakdown voltage structure region 42 on the diagonal line DL where the electric field is likely to spread, it is possible to suppress generation of a leakage current at a voltage lower than the expected breakdown voltage.

(1-4) The plurality of specific regions 43 is formed. According to this configuration, the outer wiring 52 and the drain electrode 23 can be electrically connected in a stable manner.

(1-5) The outer wiring 52 includes the first outer contact portion 52A connected to the inner wiring 51 and the second outer contact portion 52B connected to the contact region 44. Both the first outer contact portion 52A and the second outer contact portion 52B are provided in the specific region 43.

According to the configuration described above, the first outer contact portion 52A and the second outer contact portion 52B are not provided in the region other than the specific region 43 in the outer peripheral region 12. Therefore, it is possible to reduce the width dimension of the outer peripheral region 12 (the dimension in the direction perpendicular to the direction in which the outer peripheral region 12 extends as viewed in the z direction). Accordingly, it is possible to achieve miniaturization of the semiconductor device 10.

(1-6) The first outer contact portion 52A is connected to the surrounding wiring portion 53 of the inner wiring 51. According to this configuration, both the first outer contact portion 52A and the surrounding wiring portion 53 are formed in the specific region 43. Therefore, it is possible to shorten the length of the first outer contact portion 52A connected to the surrounding wiring portion 53.

(1-7) The first outer contact portion 52A is formed to surround the contact region 44. According to this configuration, it is possible to increase the area of the first outer contact portion 52A when viewed in the z direction. Accordingly, it is possible to suppress an increase in electrical resistance in the first outer contact portion 52A.

(1-8) The inner peripheral edge 42c of the breakdown voltage structure region 42 includes a curved portion 42d bulging toward each of the corner portions 12C of the outer peripheral region 12. According to this configuration, the length L1 of the breakdown voltage structure region 42 on the diagonal line DL of the outer peripheral region 12 can be increased as compared with a case where the inner peripheral edge 42c of the breakdown voltage structure region 42 is formed in a rectangular shape in which the inner peripheral edge 42c of the breakdown voltage structure region 42 does not include the curved portion 42d. Thus, it is possible to suppress generation of a leakage current at a voltage lower than the expected breakdown voltage.

(1-9) The contact region 44, which is formed in the corner portion 12C of the outer peripheral region 12 including the first outer peripheral edge 12a and the third outer peripheral edge 12c, is formed in the region including the first outer peripheral edge 12a and the third outer peripheral edge 12c.

According to the configuration described above, the contact region 44 is formed in the corner portions 12C of the outer peripheral region 12 at a position including the outer peripheral edge of the outer peripheral region 12. Therefore, the position of the recess portion 42b of the breakdown voltage structure region 42 can be provided near the first outer peripheral edge 12a and the third outer peripheral edge 12c in the direction along the diagonal line DL. Thus, it is possible to increase the length L1 of the breakdown voltage structure region 42 on the diagonal line DL while securing the area of the contact region 44 as viewed in the z direction. Since the contact regions 44 formed in other corner portions 12C are similarly formed at positions including the first to fourth outer peripheral edges 12a to 12d of the outer peripheral region 12, similar effects can be obtained.

(1-10) The portion of the contact region 44 adjacent to the breakdown voltage structure region 42 in the direction along the diagonal line DL includes the chamfered inclined portion 44a. The portion of the surrounding wiring portion 53 of the inner wiring 51 adjacent to the inclined portion 44a of the contact region 44 extends along the inclined portion 44a.

According to the configuration described above, the width dimension of the surrounding wiring portion 53 can be increased, and the size of the recess portion 42b of the breakdown voltage structure region 42 can be reduced. Thus, it is possible to increase the length L1 of the breakdown voltage structure region 42 along the diagonal line DL.

### Second Embodiment

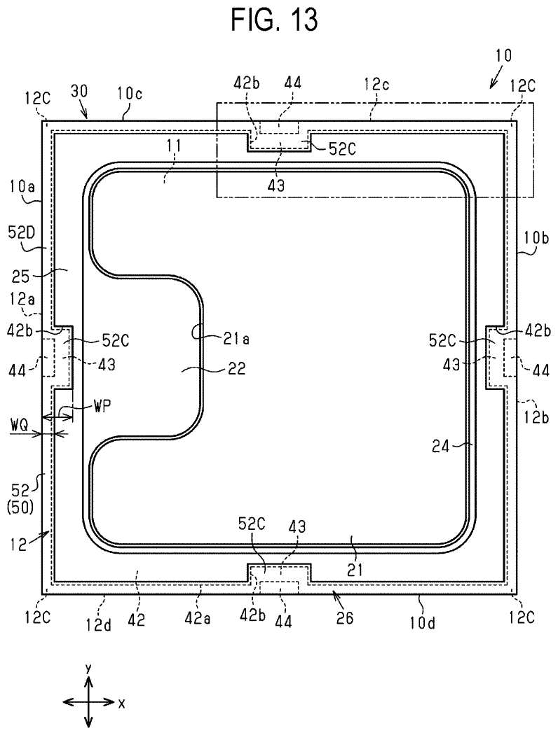

A semiconductor device 10 according to a second embodiment will be described with reference to FIGS. 13 to 16. The semiconductor device 10 of the present embodiment differs from the semiconductor device 10 of the first embodiment in the position of the specific region 43. In the following description, the same components as the components of the semiconductor device 10 of the first embodiment will be designated by like reference numerals, and the description thereof may be omitted.

As shown in FIG. 13, four recess portions 42b are provided in the outer peripheral edge 42a of the breakdown voltage structure region 42 in the outer peripheral region 12 surrounding the active region 11. The recess portions 42b are formed in the outer peripheral region 12 at a center of the first outer peripheral edge 12a in they direction, a center of the second outer peripheral edge 12b in they direction, a center of the third outer peripheral edge 12c in the x direction, and a center of the fourth outer peripheral edge 12d in the x direction, respectively.

The specific regions 43 are provided at locations corresponding to the recess portions 42b of the outer peripheral edges 42a of the breakdown voltage structure region 42. That is, the specific regions 43 are provided at four locations, i.e., at the center of the first outer peripheral edge 12a in they direction, the center of the second outer peripheral edge 12b in the y direction, the center of the third outer peripheral edge 12c in the x direction, and the center of the fourth outer peripheral edge 12d in the x direction. That is, a plurality of specific regions 43 is formed. It can also be said that the specific regions 43 are regions recessed from the outer peripheral edge 42a of the breakdown voltage structure region 42 toward the inside of the semiconductor device 10 when viewed in the z direction. On the other hand, in the present embodiment, the specific regions 43 are not formed in the corner portions 12C of the outer peripheral region 12.

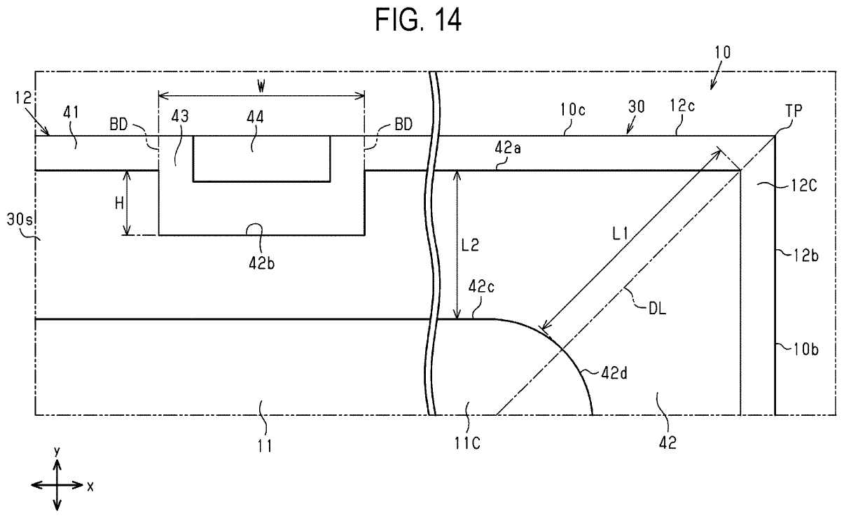

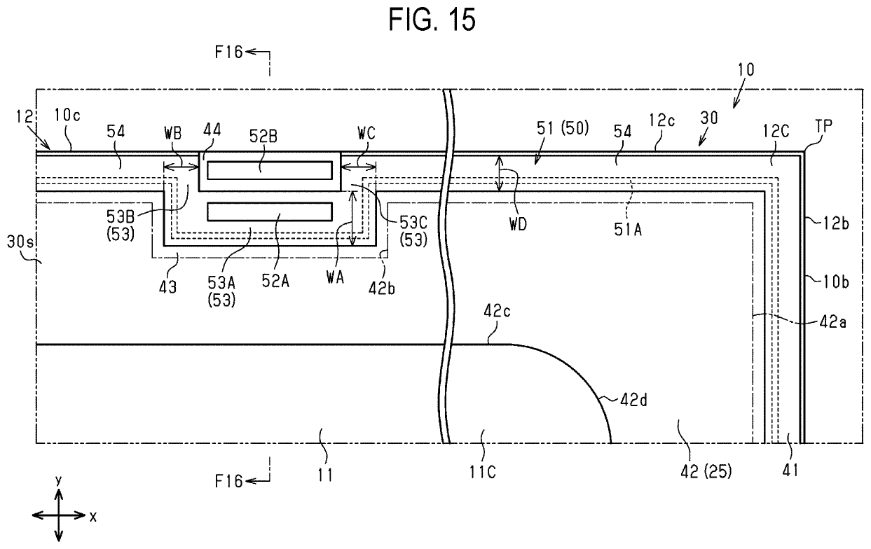

FIGS. 14 and 15 are enlarged views of the front surface 30s of the semiconductor layer 30, and shows the specific region 43 provided at the center of the third outer peripheral edge 12c of the outer peripheral region 12 in the x direction, and the corner portion 12C consisting of the second outer peripheral edge 12b and the third outer peripheral edge 12c.

As shown in FIG. 14, the shape of the specific region 43 as viewed in the z direction is a rectangular shape with long sides extending in the x direction and short sides extending in the y direction. A contact region 44 is formed in the specific region 43. In the present embodiment, the contact region 44 is not formed in the corner portion 12C of the outer peripheral region 12. Further, the contact region 44 is not formed in a ring shape surrounding the breakdown voltage structure region 42. The contact region 44 is provided more outward than the recess portion 42b of the breakdown voltage structure region 42. In the illustrated example, the contact region 44 is provided closer to the third outer peripheral edge 12c than the recess portion 42b of the breakdown voltage structure region 42. The shape of the contact region 44 as viewed in the z direction is a rectangular shape with long sides extending in the x direction and short sides extending in the y direction. That is, it can be said that the contact region 44 is formed in a rectangular shape in which long sides extend in the direction along the closest outer peripheral edge among the first to fourth outer peripheral edges 12a to 12d of the outer peripheral region 12 and short sides extend in the direction perpendicular to the closest outer peripheral edge. In addition, it can be said that the contact region 44 is formed in a rectangular shape in which when viewed in the z direction, long sides extend in the direction along the closest side surface of the semiconductor device 10 and short sides extend in the direction perpendicular to the closest side surface of the semiconductor device 10.

The recess portion 42b of the breakdown voltage structure region 42 is open toward the contact region 44. The shape of the recess portion 42b when viewed in the z direction is a rectangular concave shape having short sides and long sides. The long sides of the recess portion 42b extends in the direction along the outer peripheral edge corresponding to the recess portion 42b among the first to fourth outer peripheral edges 12a to 12d (see FIG. 13). The shape of the recess portions 42b corresponding to the first outer peripheral edge 12a and the second outer peripheral edge 12b when viewed in the z direction, respectively, is a rectangular concave shape with long sides extending in the y direction and short sides extending in the x direction. The shape of the recess portions 42b corresponding to the third outer peripheral edge 12c and the fourth outer peripheral edge 12d when viewed in the z direction, respectively, is a rectangular concave shape with short sides extending in the y direction and long sides extending in the x direction. That is, as shown in FIG. 14, a depth dimension H of the recess portion 42b of the breakdown voltage structure region 42 is smaller than an opening width W of the recess portion 42b. The opening width W of the recess portion 42b is larger than a length of the long sides of the contact region 44.

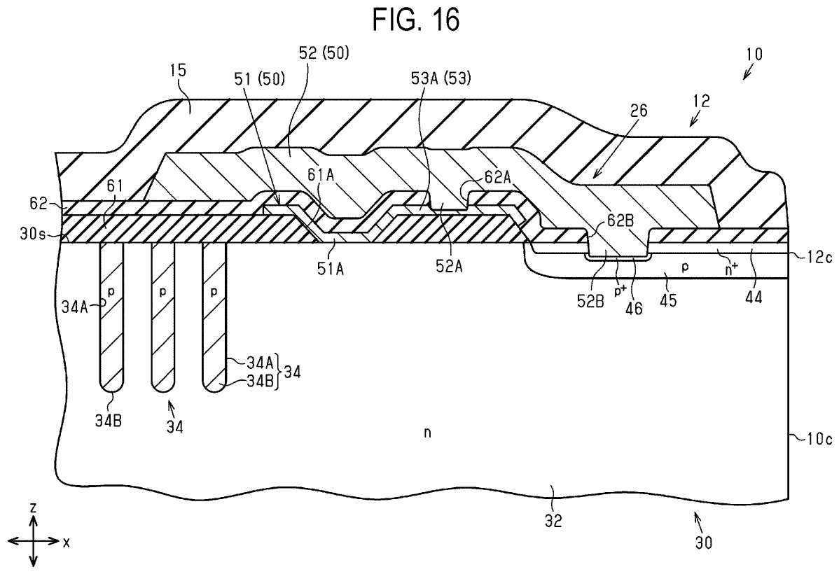

As shown in FIG. 16, a first well region 45 and a second well region 46 are formed directly below the contact region 44, as in the first embodiment. Both the first well region 45 and the second well region 46 are provided at positions overlapping with the contact region 44. That is, in the present embodiment, neither the first well region 45 nor the second well region 46 is formed in the corner portion 12C of the outer peripheral region 12. Further, the first well region 45 is provided in the specific region 43 when viewed in the z direction. That is, the first well region 45 does not protrude from the specific region 43 when viewed in the z direction.

As shown in FIG. 14, the inner peripheral edge 42c of the breakdown voltage structure region 42 has a shape conforming to the outer frame shape of the active region 11. That is, the inner peripheral edge 42c of the breakdown voltage structure region 42 has a substantially rectangular frame shape with a curved portion 42d, as in the first embodiment. Therefore, the length L1 of the breakdown voltage structure region 42 along the diagonal line DL of the outer peripheral region 12 is larger than the length L2 of the breakdown voltage structure region 42 in the direction perpendicular to one side of the outer peripheral region 12.

As shown in FIG. 15, in the present embodiment, the inner wiring 51 of the wiring 50 of the equipotential ring 26 has a different shape from the inner wiring 51 of the first embodiment when viewed in the z direction. On the other hand, a material constituting the inner wiring 51 is the same as that of the inner wiring 51 of the first embodiment.

The inner wiring 51 of the present embodiment includes surrounding wiring portions 53 and outermost peripheral wiring portions 54 as in the first embodiment. For the sake of convenience, a boundary between the surrounding wiring portions 53 and the outermost peripheral wiring portions 54 is indicated by a one-dot chain line.

Unlike the first embodiment, the surrounding wiring portions 53 are not provided in the corner portion 12C. As shown in FIG. 13, the surrounding wiring portions 53 are located at positions corresponding to the respective specific regions 43, i.e., at four positions including the center of the first outer peripheral edge 12a in they direction, the center of the second outer peripheral edge 12b in the y direction, the center of the third outer peripheral edge 12c in the x direction, and the center of the fourth outer peripheral edge 12d in the x direction, in the breakdown voltage structure region 42.

As shown in FIG. 15, the surrounding wiring portion 53 is provided in the specific region 43 and surrounds the contact region 44. In the illustrated example, the surrounding wiring portion 53 has a first portion 53A adjacent to the contact region 44 in the y direction, and a second portion 53B and a third portion 53C adjacent to the contact region 44 in the x direction. The first portion 53A is a portion that enters the recess portion 42b of the breakdown voltage structure region 42.

In the present embodiment, a width dimension WA of the first portion 53A is larger than a width dimension WB of the second portion 53B. The width dimension WA of the first portion 53A is larger than a width dimension WC of the third portion 53C. The width dimension WA of the first portion 53A is larger than a width dimension WD of the outermost peripheral wiring portion 54. The width dimension WB of the second portion 53B and the width dimension WC of the third portion 53C are equal to the width dimension WD of the outermost peripheral wiring portion 54.

Here, the width dimension WA of the first portion 53A can be defined by a dimension in the direction (y direction) orthogonal to the direction (x direction) in which the first portion 53A extends when viewed in the z direction. The width dimension WB of the second portion 53B can be defined by a dimension in the direction (x direction) orthogonal to the direction (y direction) in which the second portion 53B extends when viewed in the z direction. The width dimension WC of the third portion 53C can be defined by a dimension in the direction (x direction) orthogonal to the direction (y direction) in which the third portion 53C extends when viewed in the z direction. In the illustrated example, the width dimension WD of the outermost peripheral wiring portion 54 can be defined by a dimension in the direction (e.g., the y direction) orthogonal to the direction (e.g., the x direction) in which the outermost peripheral wiring portion 54 extends.

The outermost peripheral wiring portion 54 is a portion of the inner wiring 51 other than the surrounding wiring portion 53. Therefore, in the present embodiment, the outermost peripheral wiring portion 54 is provided at the corner portion 12C unlike the first embodiment.

The inner contact portion 51A of the inner wiring 51 is formed closer to the breakdown voltage structure region 42 than the center of the inner wiring 51 in the width direction of the inner wiring 51. The inner contact portion 51A is formed in an annular shape surrounding the breakdown voltage structure region 42. The inner contact portion 51A in the surrounding wiring portion 53 is formed in the same shape as the surrounding wiring portion 53 when viewed in the z direction.

As shown in FIG. 13, the outer wiring 52 is formed in a ring shape extending along the outer periphery of the front surface 30s of the semiconductor layer 30. The outer wiring 52 is formed to cover the specific region 43. Therefore, a width dimension WP of the first outer wiring 52C corresponding to the specific region 43 of the outer wiring 52 is larger than a width dimension WQ of the second outer wiring 52D corresponding to the region other than the specific region 43 of the outer wiring 52.

The outer wiring 52 has a first outer contact portion 52A connected to the inner wiring 51 and a second outer contact portion 52B connected to the contact region 44, as in the first embodiment.

As shown in FIG. 16, the first outer contact portion 52A is in contact with the inner wiring 51 via the interlayer insulating film 62 in the film thickness direction (z direction). As shown in FIG. 15, the first outer contact portion 52A is provided in the specific region 43. On the other hand, the first outer contact portion 52A is not provided in a region other than the specific region 43. Therefore, the first outer contact portion 52A is not formed in an annular shape surrounding the breakdown voltage structure region 42.

The first outer contact portion 52A is provided at a position overlapping with the surrounding wiring portion 53 when viewed in the z direction. The first outer contact portion 52A is connected to the surrounding wiring portion 53. The first outer contact portion 52A is provided closer to the contact region 44 with respect to the inner contact portion 51A. It can be said that the first outer contact portion 52A is provided between the inner contact portion 51A and the contact region 44. Therefore, it can be said that the inner contact portion 51A is provided closer to the outer peripheral edge 42a of the breakdown voltage structure region 42 than the first outer contact portion 52A. The first outer contact portion 52A enters the recess portion 42b of the breakdown voltage structure region 42.

The second outer contact portion 52B is provided in the specific region 43. More specifically, the second outer contact portion 52B is provided at a position overlapping with the contact region 44 when viewed in the z direction. The second outer contact portion 52B is provided closer to the outer periphery of the outer peripheral region 12 than the inner wiring 51. Further, the second outer contact portion 52B is provided closer to the outer edge of the outer peripheral region 12 than the first outer contact portion 52A. As shown in FIG. 16, a tip of the second outer contact portion 52B is in contact with both the contact region 44 and the second well region 46 as in the first embodiment.

### (Effects)

According to the semiconductor device 10 of the present embodiment, the following effects are obtained in addition to the effects of the first embodiment.

(2-1) The specific region 43 is provided at a position different from the corner portion 12C of the outer peripheral region 12. According to this configuration, the recess portion 42b is not formed in the breakdown voltage structure region 42 at the corner portion 12C of the outer peripheral region 12. Therefore, it is possible to increase the length L1 of the breakdown voltage structure region 42 along the diagonal line DL.

(2-2) The depth dimension H of the recess portion 42b of the outer peripheral edge 42a of the breakdown voltage structure region 42 is smaller than the opening width W of the recess portion 42b. According to this configuration, it is possible to suppress reduction in the width dimension of the breakdown voltage structure region 42, which is a distance between a bottom of the recess portion 42b of the breakdown voltage structure region 42 and the inner peripheral edge 42c of the breakdown voltage structure region 42. Therefore, it is possible to suppress generation of a leakage current at a voltage lower than the expected breakdown voltage, and to reduce the size of the semiconductor device 10.

(2-3) The contact region 44 corresponding to the third outer peripheral edge 12c extends toward the inside of the semiconductor device 10 from the third outer peripheral edge 12c, and is formed into a rectangular shape with longer sides extending in the direction in which the third outer peripheral edge 12c extends when viewed in the z direction.

According to the configuration described above, the short sides of the contact region 44 corresponding to the third outer peripheral edge 12c is orthogonal to the third outer peripheral edge 12c when viewed in the z direction. Therefore, it is possible to reduce the depth dimension H of the recess portion 42b of the breakdown voltage structure region 42 adjacent to the contact region 44. Accordingly, it is possible to suppress reduction in the width dimension of the portion of the breakdown voltage structure region 42 where the recess portion 42b is formed. The same effects can be obtained for the contact region 44 corresponding to the first outer peripheral edge 12a, the contact region 44 corresponding to the second outer peripheral edge 12b, and the contact region 44 corresponding to the fourth outer peripheral edge 12d.

### [Modifications]

Each of the above-described embodiments can be modified as follows. Moreover, each of the above-described embodiments and the following modifications may be combined with one another within a technically consistent range.

In the first embodiment, at least one of the second portion 53B and the third portion 53C may be omitted from the surrounding wiring portion 53. In this case, the first portion 53A is connected to the outermost peripheral wiring portion 54. Further, the first portion 53A may be omitted from the surrounding wiring portion 53. In this case, the second portion 53B and the third portion 53C are connected to each other.

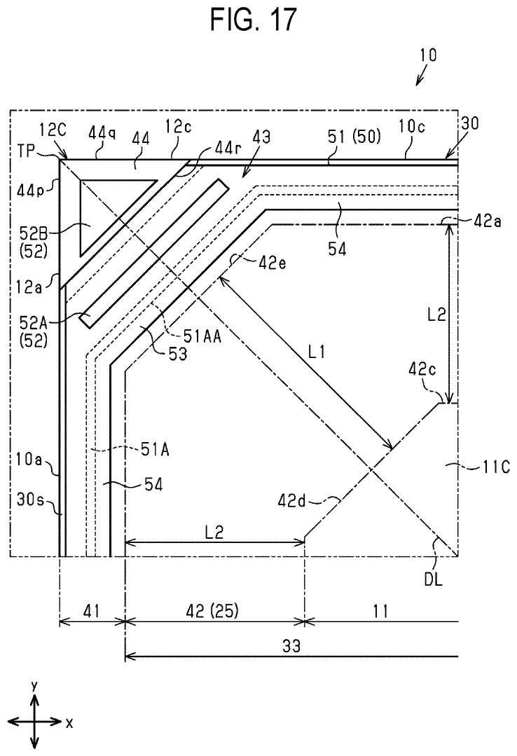

In the first embodiment, the shape of the contact region 44 in the specific region 43 and the shape of the surrounding wiring portion 53 of the inner wiring 51 may be changed arbitrarily. In one example, as shown in FIG. 17, the shape of contact region 44 may be triangular. More specifically, the contact region 44 has a first side 44p including the first outer peripheral edge 12a when viewed in the z direction, a second side 44q including the third outer peripheral edge 12c when viewed in the z direction, and a third side 44r connecting the first side 44p and the second side 44q. In the illustrated example, the third side 44r straddles the diagonal line DL and extends in the direction orthogonal to the diagonal line DL when viewed in the z direction.

The surrounding wiring portion 53 of the inner wiring 51 extends in the direction along which the third side 44r of the contact region 44 extends. The first portion 51AA of the inner contact portion 51A of the inner wiring 51 is provided at a position overlapping with the surrounding wiring portion 53 when viewed in the z direction. The first portion 51AA is provided closer to the breakdown voltage structure region 42 than the center of the surrounding wiring portion 53 in the width direction of the surrounding wiring portion 53. Here, the width direction of the surrounding wiring portion 53 is the direction extending along the diagonal line DL.

The first outer contact portion 52A of the outer wiring 52 is provided at a position overlapping with the surrounding wiring portion 53 when viewed in the z direction, and extends in the direction along which the third side 44r of the contact region 44 extends. The first outer contact portion 52A is provided between the inner contact portion 51A and the contact region 44 in the width direction of the surrounding wiring portion 53.

A chambered inclined portion 42e as a recess portion of the outer peripheral edge 42a is formed in a portion of the outer peripheral edge 42a of the breakdown voltage structure region 42 corresponding to the corner portion 12C of the outer peripheral region 12. In the illustrated example, the inclined portion 42e extends in the direction along which the third side 44r of the contact region 44 extends. In this case, the specific region 43 is formed as a region surrounded by the inclined portion 42e, the first outer peripheral edge 12a, and the third outer peripheral edge 12c.

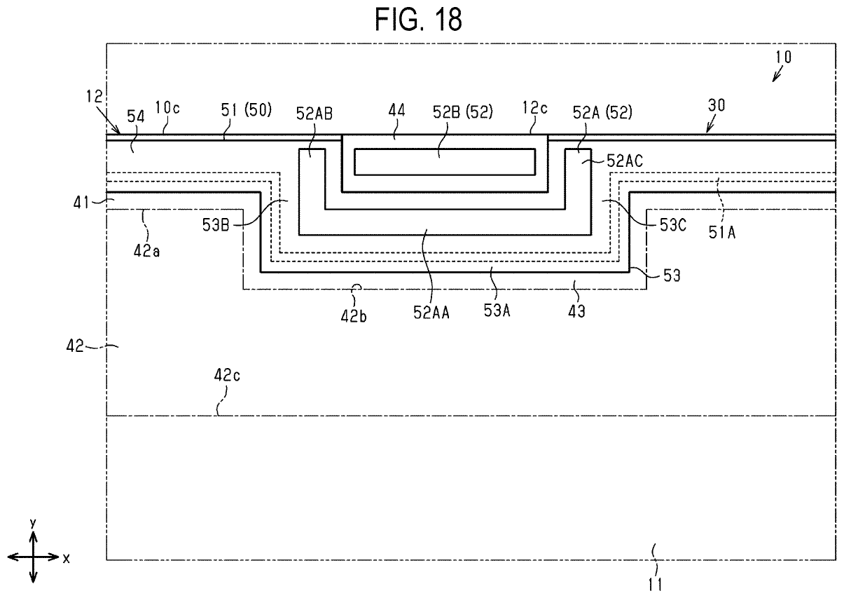

In the second embodiment, the shape of the first outer contact portion 52A of the outer wiring 52 can be changed arbitrarily. In one example, as shown in FIG. 18, the first outer contact portion 52A may be formed to surround the contact region 44 when viewed in the z direction. More specifically, the shape of the first outer contact portion 52A when viewed in the z direction is a concave shape open toward the contact region 44. It can be said that the contact region 44 enters the recess portion of the first outer contact portion 52A.

The first outer contact portion 52A includes a first portion 52AA extending in the long side direction of the contact region 44, a second portion 52AB extending from a first end of the first portion 52AA toward the third outer peripheral edge 12c, and a third portion 52AC extending from a second end of the first portion 52AA toward the third outer peripheral edge 12c. Here, the first end and the second end of the first portion 52AA are opposite ends in an extension direction of the first portion 52AA. In the illustrated example, the first end of the first portion 52AA is the end closer to the first outer peripheral edge 12a (see FIG. 13) in the extension direction of the first portion 52AA. The second end of the first portion 52AA is the end closer to the second outer peripheral edge 12b (see FIG. 13) in the extension direction of the first portion 52AA. In the illustrated example, the first portion 52AA, the second portion 52AB, and the third portion 52AC are integrally formed.

The first portion 52AA is provided at a position overlapping with the first portion 53A of the surrounding wiring portion 53 of the inner wiring 51 when viewed in the z direction. A length of the first portion 52AA in the direction in which the first portion 52AA extends is larger than a length of the long sides of the contact region 44.

The second portion 52AB is provided at a position overlapping with the first portion 53A and the second portion 53B of the surrounding wiring portion 53 when viewed in the z direction. The second portion 52AB is provided between the inner contact portion 51A of the inner wiring 51 and the contact region 44 in the x direction when viewed in the z direction. Therefore, in the illustrated example, a width dimension of the second portion 53B of the surrounding wiring portion 53 is larger than a width dimension of the second portion 53B of the surrounding wiring portion 53 of the second embodiment. In one example, the width dimension of the second portion 53B of the surrounding wiring portion 53 is equal to the width dimension of the first portion 53A.

The third portion 52AC is provided at a position overlapping with the first portion 53A and the third portion 53C of the surrounding wiring portion 53 when viewed in the z direction. The third portion 52AC is provided between the inner contact portion 51A and the contact region 44 in the x direction when viewed in the z direction. Therefore, in the illustrated example, a width dimension of the third portion 53C of the surrounding wiring portion 53 is larger than a width dimension of the third portion 53C of the surrounding wiring portion 53 of the second embodiment. The width dimension of the third portion 53C of the surrounding wiring portion 53 is equal to the width dimension of the first portion 53A.

In each embodiment, the second well region 46 may be omitted. In this case, the second outer contact portion 52B of the outer wiring 52 is in contact with the first well region 45. Further, both the first well region 45 and the second well region 46 may be omitted. In this case, a tip of the second outer contact portion 52B is in contact with the contact region 44. That is, the second outer contact portion 52B does not penetrate the contact region 44.

In each embodiment, the number of the specific regions 43 can be changed arbitrarily. In one example, there may be one, two, or three specific regions 43. Further, the number of specific regions 43 may be five or more. In addition, the contact regions 44 are provided according to the number of the specific regions 43. For example, when there is one specific region 43, one contact region 44 is provided.

In each embodiment, a layout of the column regions 34 in the SJ region 33 can be changed arbitrarily. In one example, a plurality of column regions 34 may be arranged in a grid pattern in the SJ region 33.

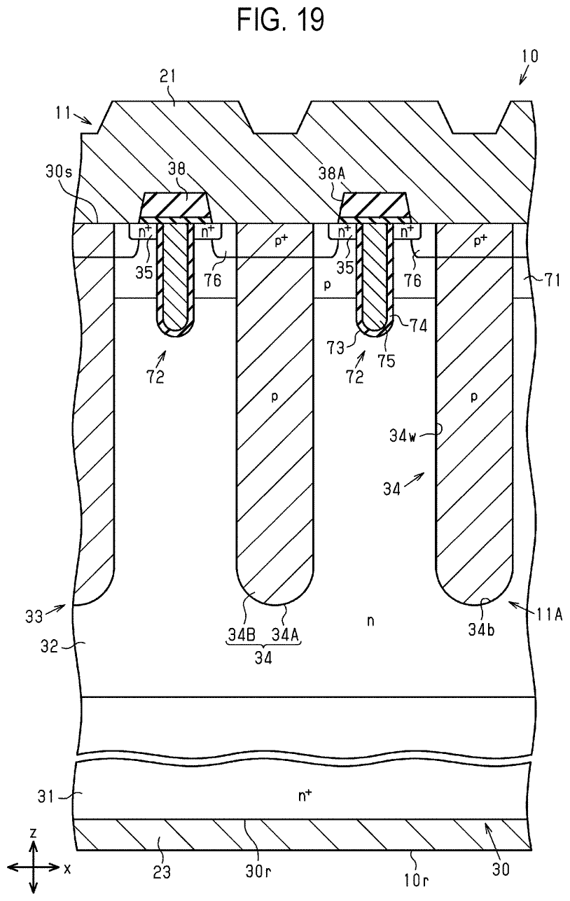

In each embodiment, a cell structure of the active region 11 can be changed arbitrarily. In one example, as shown in FIG. 19, the semiconductor device 10 may have a trench gate structure. More specifically, a p-type channel region 71 is formed on the front surface 30s of the semiconductor layer 30 in the active region 11. The channel region 71 is also called a body region. The channel region 71 is formed, for example, over the entire active region 11. A concentration of p-type impurities in the channel region 71 is higher than, for example, a concentration of p-type impurities in the polysilicon 34B of the column region 34. The p-type impurity concentration in the channel region 71 is, for example, 1×10¹⁵ cm⁻³ or more and 1×10¹⁸ cm⁻³ or less.

The semiconductor device 10 has a plurality of trench gate structures 72 formed on the front surface 30s of the semiconductor layer 30 in the active region 11. Each trench gate structure 72 is formed from the channel region 71 to the drift region 32. Each trench gate structure 72 includes a trench 73, a gate insulating layer 74, and a gate electrode 75.

Each trench 73 is formed by digging the front surface 30s of the semiconductor layer 30 toward the rear surface 30r. A depth dimension of each trench 73 (a dimension of each trench 73 in the z direction) is smaller than a depth dimension of each column region 34 (a dimension of each column region 34 in the z direction). The depth dimension of each trench 73 is, for example, 0.1 μm or more and 5 μm or less.

The gate insulating layer 74 is formed on an inner wall of each trench 73. The gate insulating layer 74 may include at least one of a SiO₂ layer, a silicon nitride (SiN) layer, a silicon nitride oxide (SiON) layer, an aluminum oxide (AlO) layer, a hafnium silicate (HfSiO) layer, and a nitrogen-added hafnium silicate (HfSiON) layer. In one example, the gate insulating layer 74 is formed of a silicon oxide film.

The gate electrode 75 is provided on the gate insulating layer 74 and embedded in the trench 73. The gate electrode 75 is made of, for example, polysilicon. The source regions 35 are formed near the front surface 30s of the semiconductor layer 30 in the channel region 71. The source regions 35 are formed on both sides of each trench 73 in an arrangement direction of the plurality of trenches 73.

The semiconductor device 10 has a plurality of p⁺-type contact regions 76 formed near the front surface 30s of the semiconductor layer 30 in the active region 11. The contact regions 76 are also called in-base regions. A concentration of p-type impurities in the contact regions 76 is higher than the p-type impurity concentration in the polysilicon 34B of the column region 34. The p-type impurity concentration in the contact regions 76 is, for example, 1×10¹⁹ cm⁻³ or more and 1×10²¹ cm⁻³ or less.

The contact regions 76 are formed at intervals on a lateral side of the trenches 73 in the arrangement direction of the trenches 73. Each contact region 76 is formed to overlap with the column region 34. Each contact region 76 is formed wider than the column region 34. Each contact region 76 is connected to the source region 35. Thus, in the illustrated example, an FET structure including the channel region 71, the trench gate structure 72, and the source region 35 is formed in the active region 11.

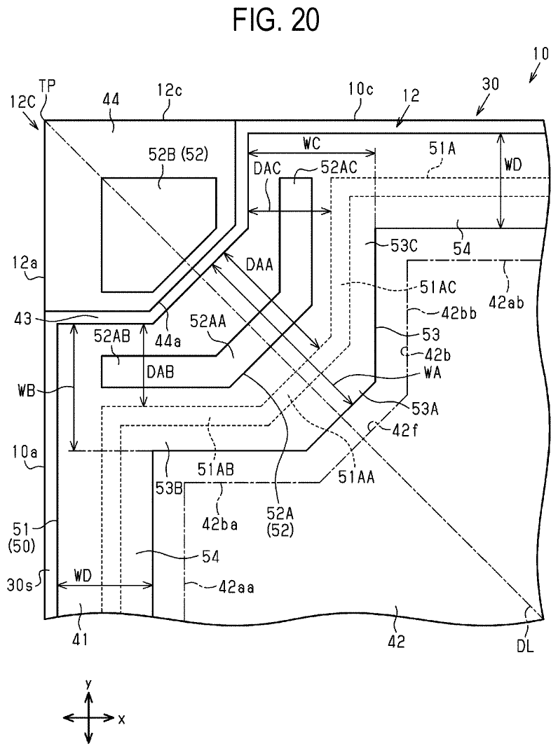

In the first embodiment, the shape of the recess portion 42b of the breakdown voltage structure region 42 can be changed arbitrarily. In one example, as shown in FIG. 20, a chamfered inclined portion 42f is formed between the straight lines 42ba and 42bb of the recess portion 42b. In the illustrated example, the inclined portion 42f is inclined from the fourth outer peripheral edge 12d (see FIG. 3) toward the third outer peripheral edge 12c as it extends from the first outer peripheral edge 12a toward the second outer peripheral edge 12b (see FIG. 3).

According to the configuration described above, the length L1 of the breakdown voltage structure region 42 along the diagonal line DL can be increased. The shape of the recess portion 42b is not limited to the shape shown in FIG. 20. For example, a step-shaped portion may be formed between the straight lines 42ba and 42bb of the recess portion 42b.

In each embodiment, the structure of the outer peripheral region 12 can be changed arbitrarily. In one example, the recess portion 42b (see FIG. 9) of the breakdown voltage structure region 42 may be omitted. In this case, the contact region 44 may be formed, for example, at a position adjacent to two outer peripheral edges apart from each other among the first to fourth outer peripheral edges 12a to 12d of the outer peripheral region 12. More specifically, the non-column region 41 of the semiconductor device 10 is a region (outermost peripheral region) constituting the outermost periphery of the outer peripheral region 12, and is formed in a ring shape including the first to fourth outer peripheral edges 12a to 12d. The non-column region 41 includes a first outermost peripheral region 12P and a second outermost peripheral region 12Q as two regions having different structures. The first outermost peripheral region 12P is a region including the specific region 43. The contact region 44 is formed in the specific region 43. The second outermost peripheral region 12Q is a region in which the inner wiring 51 is formed.

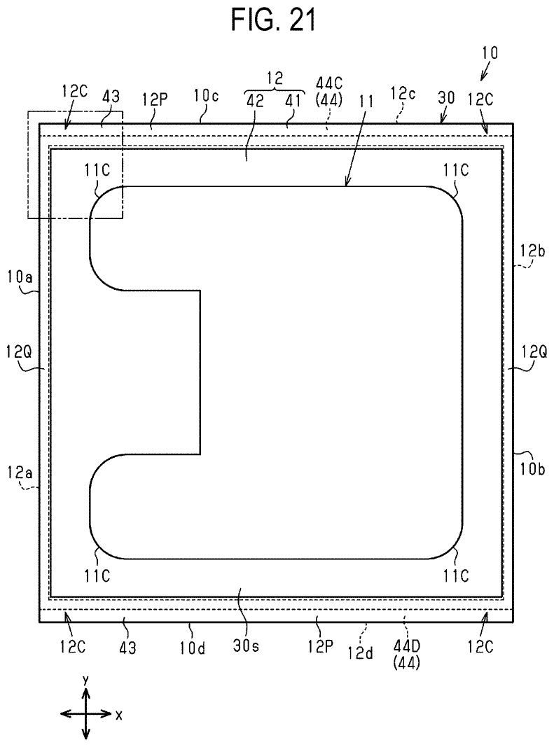

In one example, as shown in FIG. 21, the first outermost peripheral region 12P is provided at positions adjacent to the third outer peripheral edge 12c and the fourth outer peripheral edge 12d in they direction. Therefore, the contact region 44 is provided at positions adjacent to the third outer peripheral edge 12c and the fourth outer peripheral edge 12d in the y direction.

A contact region 44C provided in the first outermost peripheral region 12P (specific region 43) adjacent to the device side surface 10c in they direction is formed over the entire third outer peripheral edge 12c along the direction (x direction) in which the third outer peripheral edge 12c extends. In the illustrated example, the contact region 44C includes the third outer peripheral edge 12c when viewed in the z direction. Further, when viewed in the z direction, the contact region 44C includes the first outer peripheral edge 12a and the second outer peripheral edge 12b. That is, both edges of the contact region 44C in the x direction extend to the first outer peripheral edge 12a and the second outer peripheral edge 12b.

A contact region 44D provided in the first outermost peripheral region 12P (specific region 43) adjacent to the fourth outer peripheral edge 12d in the y direction is formed over the entire fourth outer peripheral edge 12d along the direction (x direction) in which the fourth outer peripheral edge 12d extends. In the illustrated example, the contact region 44D includes the fourth outer peripheral edge 12d when viewed in the z direction. Further, when viewed in the z direction, the contact region 44D includes the first outer peripheral edge 12a and the second outer peripheral edge 12b. That is, both edges of the contact region 44D in the x direction extend to the first outer edge 12a and the second outer peripheral edge 12b.

The second outermost peripheral region 12Q is provided at positions adjacent to the first outer peripheral edge 12a and the second outer peripheral edge 12b in the x direction. At the positions adjacent to the first outer peripheral edge 12a and the second outer peripheral edge 12b in the x direction, the contact region 44 is not provided but the inner wiring 51 is provided.

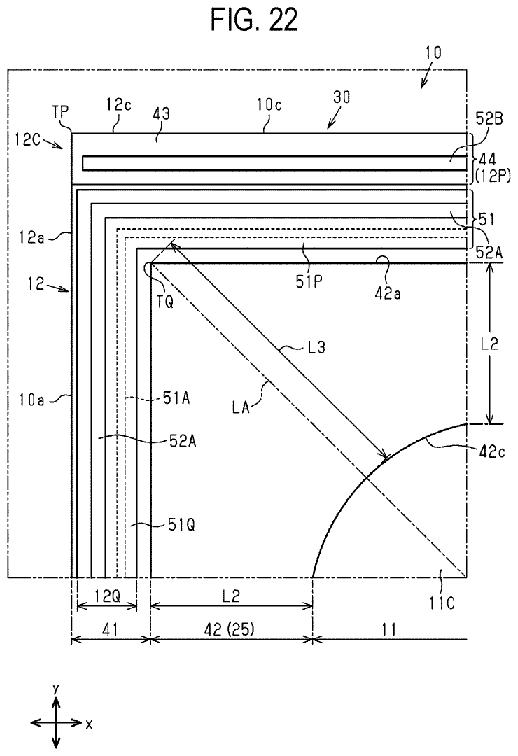

FIG. 22 shows an enlarged view of a vicinity of the first outer peripheral edge 12a in the first outermost peripheral region 12P. As shown in FIG. 22, the recess portion 42b of the breakdown voltage structure region 42 is omitted. Therefore, the corner portion of the breakdown voltage structure region 42 is formed in a rectangular shape. Thus, a length L3 of the breakdown voltage structure region 42 along a diagonal line LA of the outer peripheral region 12 is increased. Here, the diagonal line LA of the outer peripheral region 12 is different from the diagonal line DL of the first embodiment. The diagonal line LA is formed by a straight line connecting an apex TQ of the corner portion of the breakdown voltage structure region 42 and the center of the semiconductor layer 30. The length L3 of the breakdown voltage structure region 42 on the diagonal line LA is a length of the breakdown voltage structure region 42 on the diagonal line LA.

The inner wiring 51 is formed over the entire circumference of the semiconductor layer 30 when viewed in the z direction. The inner wiring 51 includes a first inner wiring portion 51P extending along the third outer peripheral edge 12c and the fourth outer peripheral edge 12d, and a second inner wiring portion 51Q extending along the first outer peripheral edge 12a and the second outer peripheral edge 12b. The first inner wiring portion 51P is a portion of the inner wiring 51 between the contact region 44 and the breakdown voltage structure region 42 in the y direction. The second inner wiring portion 51Q is formed in the second outermost peripheral region 12Q.

In the illustrated example, the width dimension of the inner wiring 51 is constant. In one example, the width dimension of the inner wiring 51 is equal to the width dimension WB (see FIG. 9) of the second portion 53B of the surrounding wiring portion 53 in each of the above-described embodiments. The inner contact portion 51A is formed over the entire circumference of the inner wiring 51 as in each of the above-described embodiments.

According to such a configuration, since the length L3 of the breakdown voltage structure region 42 along the diagonal line LA can be increased, it is possible to suppress generation of a leakage current at a voltage lower than the expected breakdown voltage. In addition, the size of the semiconductor device 10 in the x direction can be reduced by the amount that the contact region 44 is not formed at the positions adjacent to the first outer peripheral edge 12a and the second outer peripheral edge 12b.

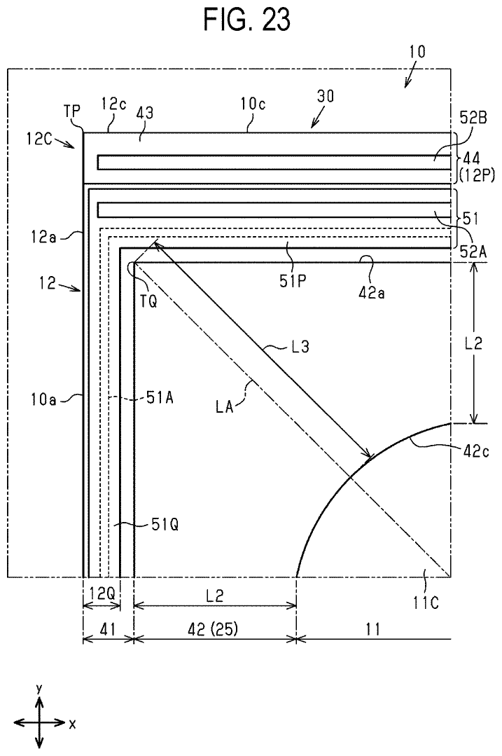

In the modification shown in FIG. 21, the configuration of the second outermost peripheral region 12Q can be changed arbitrarily. In one example, as shown in FIG. 23, the first outer contact portion 52A may not be formed in the second inner wiring portion 51Q. In this case, a width dimension of the second inner wiring portion 51Q is smaller than a width dimension of the first inner wiring portion 51P. As a result, it is possible to reduce the size of the semiconductor device 10 in the x direction.

In the modification shown in FIG. 21, the first outermost peripheral region 12P may be provided at positions adjacent to the first outer peripheral edge 12a and the second outer peripheral edge 12b in the x direction, and the second outermost peripheral region 12Q may be provided at position adjacent to the third outer peripheral edge 12c and the fourth outer peripheral edge 12d in they direction.

In the modification shown in FIG. 21, the first outermost peripheral region 12P may be provided at a position adjacent to one of the first to fourth outer peripheral edges 12a to 12d. That is, the second outermost peripheral region 12Q is provided at positions adjacent to the remaining three outer peripheral edges among the first to fourth outer peripheral edges 12a to 12d.

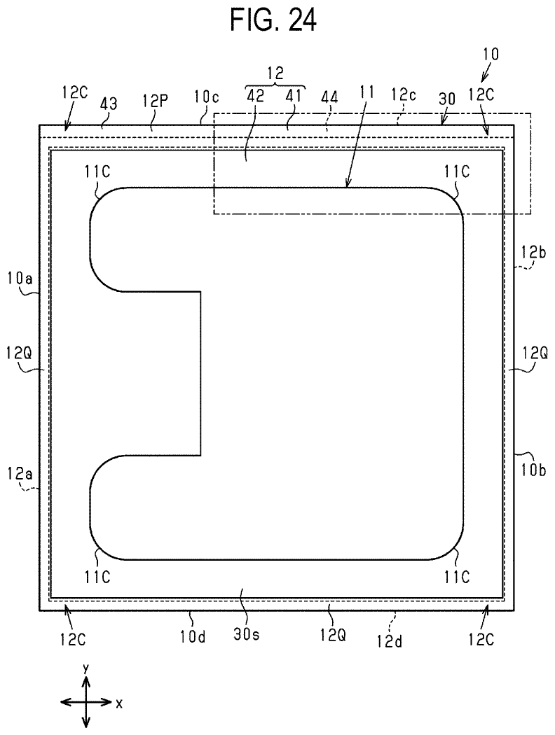

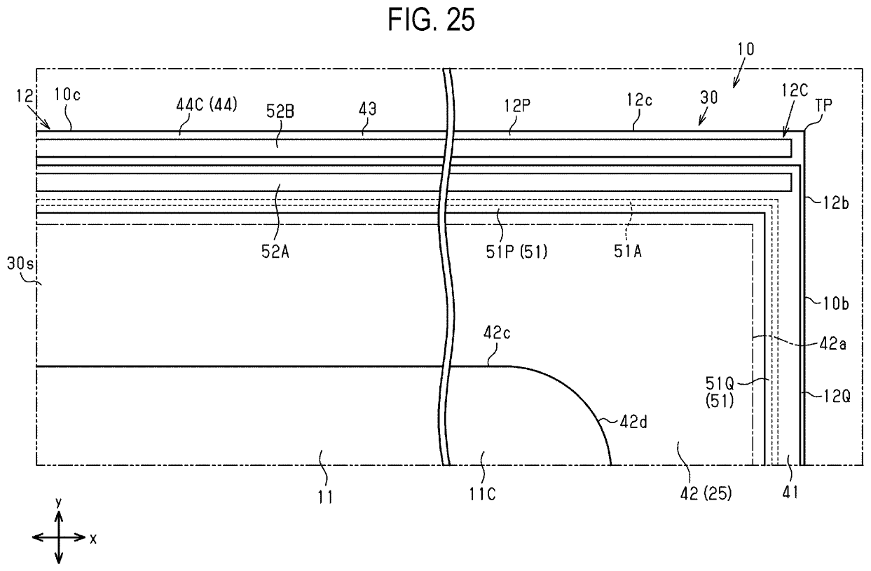

In one example, as shown in FIG. 24, the first outermost peripheral region 12P may be provided at a position adjacent to the third outer peripheral edge 12c. In this case, as shown in FIG. 25, the first outer contact portion 52A is provided only in a portion of the inner wiring 51 adjacent to the contact region 44 in they direction. As described above, the first outermost peripheral region 12P and the second outermost peripheral region 12Q each may include one or more of the outer peripheral edges that are different from each other, among the first to fourth outer peripheral edges 12a to 12d.

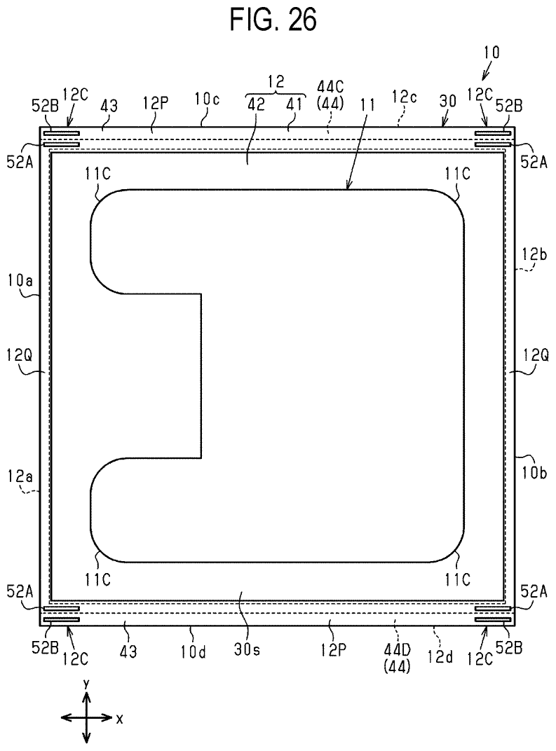

In the modification shown in FIG. 21, the length of the first outer contact portion 52A and the length of the second outer contact portion 52B can be changed arbitrarily. An example of the length of each of the outer contact portions 52A and 52B is shown in FIG. 26. FIG. 26 shows each of the outer contact portions 52A and 52B in a schematic plan view of the semiconductor layer 30 for the sake of convenience.

As shown in FIG. 26, both the first outer contact portion 52A and the second outer contact portion 52B are provided at each corner portion 12C of the outer peripheral region 12. In other words, neither the first outer contact portion 52A nor the second outer contact portion 52B is provided in the region between the adjacent corner portions 12C. It can be said that the second outer contact portions 52B are provided at both ends of the contact regions 44C and 44D in the x direction.

Although both the length of the first outer contact portion 52A and the length of the second outer contact portion 52B are shortened in the modification shown in FIG. 26, the present disclosure is not limited thereto. Either the length of the first outer contact portion 52A or the length of the second outer contact portion 52B may be shortened. Further, the positions of the first outer contact portion 52A and the second outer contact portion 52B are not limited to the corner portion 12C of the outer peripheral region 12 shown in FIG. 26, and can be changed arbitrarily. Similarly, in the modification shown in FIG. 24, at least one of the length of the first outer contact portion 52A and the length of the second outer contact portion 52B may be shortened as shown in FIG. 26.

In each embodiment, a structure in which the conductivity type of each region in the semiconductor layer 30 is reversed may be adopted. That is, the p-type region may be converted to an n-type region, and the n-type region may be converted to a p-type region.

The semiconductor layer 30 of the semiconductor device 10 in each embodiment is not limited to the SJ structure in which the SJ region 33 is formed, and may be a planar structure or a gate trench structure in which the column region 34 is not formed. In this case, the breakdown voltage structure region 42 may have a structure in which the column region 34 is not formed, for example, a trench field plate structure.

One or more of the various examples described herein may be combined as long as they are not technically inconsistent. In this specification, “at least one of A and B” should be understood as meaning “only A, only B, or both A and B.”

The term “on” as used herein includes the meaning of both “on” and “above” unless the context clearly indicates otherwise. Thus, the phrase “a first member is formed on a second member” is intended to mean that in a certain embodiment, the first member may be placed directly on the second member in contact with the second member, but in another embodiment, the first member may be disposed above the second member without contacting the second member. That is, the term “on” does not exclude a structure in which another member is formed between the first member and the second member.

The z direction as used herein is not necessarily vertical, nor does it need to be perfectly vertical. Thus, in the various structures according to the present disclosure, “top” and “bottom” in the z direction described herein are not limited to “top” and “bottom” in the vertical direction. For example, the x direction may be the vertical direction, or the y direction may be the vertical direction.

### [Supplementary Notes]

The technical ideas that can be recognized from the above-described embodiments and modifications are described below. For the purpose of easier understanding and not for the purpose of limitation, the corresponding reference numerals used in the embodiments are indicated in parentheses for the configurations described in the supplementary notes. Reference numerals are indicated as examples for easier understanding, and the components described in each supplementary note are not limited to the components indicated by the reference numerals.

(Supplementary Note 1)

A semiconductor device (10) provided with a semiconductor layer (30), which includes an active region (11) and an outer peripheral region (12) formed in a frame shape surrounding the active region (11) and having rectangular outer peripheral edges (12a to 12d),

wherein the outer peripheral region (12) includes:
a breakdown voltage structure region (42) in which a breakdown voltage structure is formed; and
a specific region (43) extending from the outer peripheral edges (12a to 12d) of the outer peripheral region (12) to an outer peripheral edge of the breakdown voltage structure region (42) and formed so that when viewed in a thickness direction of the semiconductor layer (30) (z direction), the outer peripheral edge (42a) of the breakdown voltage structure region (42) is recessed toward the active region (11),

wherein a contact region (44) is formed on a front surface (30s) of the semiconductor layer (30) in the specific region (43), and

wherein a wiring (50) electrically connected to the contact region (44) is formed in an outermost peripheral region (41) of the outer peripheral region (12).

(Supplementary Note 2)

The semiconductor device of Supplementary Note 1, wherein the specific region (43) is formed in a corner portion (12C) of the outer peripheral region (12).

(Supplementary Note 3)

The semiconductor device of Supplementary Note 2, wherein a length (L1) of the breakdown voltage structure region (42) on a diagonal line (DL) of the outer peripheral region (12) is larger than a length (L2) of the breakdown voltage structure region (42) in a direction perpendicular to one side of the outer peripheral region (12).

(Supplementary Note 4)

The semiconductor device of any one of Supplementary Notes 1 to 3, wherein the specific region (43) includes a plurality of specific regions (43).

(Supplementary Note 5)

The semiconductor device of any one of Supplementary Notes 1 to 4, wherein the wiring (50) includes an inner wiring (51) and an outer wiring (52), which is electrically connected to both the inner wiring (51) and the contact region (44).

(Supplementary Note 6)

The semiconductor device of Supplementary Note 5, wherein the outer wiring (52) includes a first outer contact portion (52A) connected to the inner wiring (51),

wherein the inner wiring (51) includes an inner contact portion (51A) connected to the semiconductor layer (30), and

wherein the inner contact portion (51A) is provided closer to the outer peripheral edge (42a) of the breakdown voltage structure region (42) than the first outer contact portion (52A).

(Supplementary Note 7)

The semiconductor device of Supplementary Note 6, wherein the outer wiring (52) includes a second outer contact portion (52B) connected to the contact region (44), and

wherein both the first outer contact portion (52A) and the second outer contact portion (52B) are provided in the specific region (43).

(Supplementary Note 8)

The semiconductor device of Supplementary Note 6 or 7, wherein the inner wiring (51) includes a surrounding wiring portion (53) configured to surround the contact region (44) when viewed in the thickness direction of the semiconductor layer (30) (z direction), and an outermost peripheral wiring portion (54) formed in the outermost peripheral region (41), and

wherein a width dimension (WD) of the outermost peripheral wiring portion (54) is smaller than a width dimension (WB) of the surrounding wiring portion (53).

(Supplementary Note 9)

The semiconductor device of Supplementary Note 8, wherein the first outer contact portion (52A) is connected to the surrounding wiring portion (53).

(Supplementary Note 10)

The semiconductor device of Supplementary Note 9, wherein the first outer contact portion (52A) is formed to surround the contact region (44).

(Supplementary Note 11)

The semiconductor device of Supplementary Note 2 or 3, wherein an inner peripheral edge (42c) of the breakdown voltage structure region (42) includes a curved portion (42d) bulging toward the corner portion (12C) of the outer peripheral region (12).

(Supplementary Note 12)

The semiconductor device of any one of Supplementary Notes 1 to 11, wherein the semiconductor layer (30) includes a super junction region (33) in which first conductivity type drift regions (32) and second conductivity type column regions (34) are alternately arranged.

(Supplementary Note 13)

The semiconductor device of Supplementary Note 12, wherein the column regions (34) are not formed in the specific region (43), and the drift regions (32) are formed in the specific region (43).

(Supplementary Note 14)

The semiconductor device of Supplementary Note 12 or 13, wherein the column regions (34) are formed in a stripe shape extending along one side of the outer peripheral region (12) when viewed in the thickness direction of the semiconductor layer (30) (z direction).

(Supplementary Note 15)

The semiconductor device of any one of Supplementary Notes 1 to 14, wherein the breakdown voltage structure region (42) is a region in which first conductivity type drift regions (32) and second conductivity type column regions (34) are alternately arranged.

(Supplementary Note 16)

A semiconductor device provided with a semiconductor layer (30), which includes an active region (11) and an outer peripheral region (12) formed in a frame shape surrounding the active region (11),

wherein the outer peripheral region (12) includes four rectangular outer peripheral edges (12a to 12d),

wherein the outer peripheral region (12) further includes:
a breakdown voltage structure region (42) in which a breakdown voltage structure is formed; and
a specific region (43) formed between the breakdown voltage structure region (42) and the outer peripheral edges (12a to 12d) of the outer peripheral region (12),

wherein a contact region (44) is formed on a front surface (30s) of the semiconductor layer (30) in the specific region (43),

wherein an outermost peripheral region (41) of the outer peripheral region (12) includes a first outermost peripheral region (12P) formed by the specific region (43), and a second outermost peripheral region (12Q) in which a wiring (50) electrically connected to the contact region (44) is formed, and

wherein the first outermost peripheral region (12P) and the second outermost peripheral region (12Q) each include one or more of the outer peripheral edges that are different from each other.

(Supplementary Note 17)

The semiconductor device of Supplementary Note 16, wherein the four outer peripheral edges of the outer peripheral region (12) include a first outer peripheral edge (12a) and a second outer peripheral edge (12b) spaced apart from each other, and a third outer peripheral edge (12c) and a fourth outer peripheral edge (12d) orthogonal to the first outer peripheral edge (12a) and the second outer peripheral edge (12b) and spaced apart from each other,

wherein the first outermost peripheral region (12P) is formed to include the third outer peripheral edge (12c) and the fourth outer peripheral edge (12d), and

wherein the second outermost peripheral region (12Q) is formed to include a region between the first outer peripheral edge (12a) and the breakdown voltage structure region (42) and a region between the second outer peripheral edge (12b) and the breakdown voltage structure region (42).

(Supplementary Note 18)

The semiconductor device of Supplementary Note 16, wherein the four outer peripheral edges of the outer peripheral region (12) include a first outer peripheral edge (12a) and a second outer peripheral edge (12b) spaced apart from each other, and a third outer peripheral edge (12c) and a fourth outer peripheral edge (12d) orthogonal to the first outer peripheral edge (12a) and the second outer peripheral edge (12b) and spaced apart from each other,

wherein the first outermost peripheral region (12P) is formed to include one of the first outer peripheral edge (12a), the second outer peripheral edge (12b), the third outer peripheral edge (12c), and the fourth outer peripheral edge (12d), and

wherein the second outermost peripheral region (12Q) is formed to include the remaining three outer peripheral edges other than the outer peripheral edge included in the first outermost peripheral region (12P).

(Supplementary Note 19)

The semiconductor device of Supplementary Note 2 or 3, wherein a portion of the contact region (44) adjacent to the breakdown voltage structure region (42) in a direction along the diagonal line (DL) of the outer peripheral region (12) includes a chamfered inclined portion (44a),

wherein the wiring (50) includes an inner wiring (51),

wherein the inner wiring (51) includes a surrounding wiring portion (53) configured to surround the contact region (44) when viewed in the thickness direction of the semiconductor layer (30) (z direction), and an outermost peripheral wiring portion (54) formed in the outermost peripheral region (41), and

wherein a portion of the surrounding wiring portion (53) adjacent to the inclined portion (44a) of the contact region (44) extends along the inclined portion (44a).

(Supplementary Note 20)

The semiconductor device of Supplementary Note 2, 3, or 19, wherein the outer peripheral edges of the outer peripheral region (12) include a first outer peripheral edge (12a) and a second outer peripheral edge (12b) spaced apart from each other, and a third outer peripheral edge (12c) and a fourth outer peripheral edge (12d) orthogonal to the first outer peripheral edge (12a) and the second outer peripheral edge (12b) and spaced apart from each other,

wherein an outer peripheral edge (42a) of the breakdown voltage structure region (42) includes a recess portion (42b) into which the specific region (43) enters, and

wherein the recess portion (42b) has a step shape defined by a first straight line (42ba) extending along the third outer peripheral edge (12c) and a second straight line (42bb) extending along the first outer peripheral edge (12a).

(Supplementary Note 21)

The semiconductor device of Supplementary Note 8, wherein a width direction of the surrounding wiring portion (53) is a direction orthogonal to an extension direction of the surrounding wiring portion (53) when viewed in the thickness direction of the semiconductor layer (30) (z direction), and

wherein the inner contact portion (51A) is provided closer to the outer peripheral edge (42a) of the breakdown voltage structure region (42) than a center of the surrounding wiring portion (53) in the width direction.

(Supplementary Note 22)

The semiconductor device of Supplementary Note 1, wherein the specific region (43) is provided in a region different from a corner portion (12C) of the outer peripheral region (12), and

wherein the contact region (44) provided in the specific region (43) is formed to include the outer peripheral edge (12c) of the outer peripheral region (12), and is formed in a rectangular shape having long sides extending in an extension direction of the outer peripheral edge (12c) of the outer peripheral region (12) when viewed in the thickness direction of the semiconductor layer (30) (z direction).

The above description is merely exemplary. Those skilled in the art will be able to recognize that many more possible combinations and permutations can be made in addition to the components and methods (manufacturing processes) listed for the purpose of describing the technique of the present disclosure. The present disclosure is intended to cover all alternatives, variations and modifications that fall within the scope of the present disclosure including the claims.

According to the present disclosure in some embodiments, it is possible to reduce a size of an outer peripheral region of a semiconductor device.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device provided with a semiconductor layer, which includes an active region and an outer peripheral region formed in a frame shape surrounding the active region and having rectangular outer peripheral edges,
wherein the outer peripheral region includes:
a breakdown voltage structure region in which a breakdown voltage structure is formed; and
a specific region extending from the outer peripheral edges of the outer peripheral region to an outer peripheral edge of the breakdown voltage structure region, and formed so that when viewed in a thickness direction of the semiconductor layer, the outer peripheral edge of the breakdown voltage structure region is recessed toward the active region,
wherein a contact region is formed on a front surface of the semiconductor layer in the specific region, and
wherein a wiring electrically connected to the contact region is formed in an outermost peripheral region of the outer peripheral region.

2. The semiconductor device of claim 1, wherein the specific region is formed in a corner portion of the outer peripheral region.

3. The semiconductor device of claim 2, wherein a length of the breakdown voltage structure region on a diagonal line of the outer peripheral region is larger than a length of the breakdown voltage structure region in a direction perpendicular to one side of the outer peripheral region.

4. The semiconductor device of claim 1, wherein the specific region includes a plurality of specific regions.

5. The semiconductor device of claim 1, wherein the wiring includes an inner wiring and an outer wiring, which is electrically connected to both the inner wiring and the contact region.

6. The semiconductor device of claim 5, wherein the outer wiring includes a first outer contact portion connected to the inner wiring,
wherein the inner wiring includes an inner contact portion connected to the semiconductor layer, and
wherein the inner contact portion is provided closer to the outer peripheral edge of the breakdown voltage structure region than the first outer contact portion.

7. The semiconductor device of claim 6, wherein the outer wiring includes a second outer contact portion connected to the contact region, and
wherein both the first outer contact portion and the second outer contact portion are provided in the specific region.

8. The semiconductor device of claim 6, wherein the inner wiring includes a surrounding wiring portion configured to surround the contact region when viewed in the thickness direction of the semiconductor layer, and an outermost peripheral wiring portion formed in the outermost peripheral region, and
wherein a width dimension of the outermost peripheral wiring portion is smaller than a width dimension of the surrounding wiring portion.

9. The semiconductor device of claim 8, wherein the first outer contact portion is connected to the surrounding wiring portion.

10. The semiconductor device of claim 9, wherein the first outer contact portion is formed to surround the contact region.

11. The semiconductor device of claim 2, wherein an inner peripheral edge of the breakdown voltage structure region includes a curved portion bulging toward the corner portion of the outer peripheral region.

12. The semiconductor device of claim 1, wherein the semiconductor layer includes a super junction region in which first conductivity type drift regions and second conductivity type column regions are alternately arranged.

13. The semiconductor device of claim 12, wherein the column regions are not formed in the specific region, and the drift regions are formed in the specific region.

14. The semiconductor device of claim 12, wherein the column regions are formed in a stripe shape extending along one side of the outer peripheral region when viewed in the thickness direction of the semiconductor layer.

15. The semiconductor device of claim 1, wherein the breakdown voltage structure region is a region in which first conductivity type drift regions and second conductivity type column regions are alternately arranged.

16. A semiconductor device provided with a semiconductor layer, which includes an active region and an outer peripheral region formed in a frame shape surrounding the active region,
wherein the outer peripheral region includes four rectangular outer peripheral edges,
wherein the outer peripheral region further includes:
a breakdown voltage structure region in which a breakdown voltage structure is formed; and
a specific region formed between the breakdown voltage structure region and the outer peripheral edges of the outer peripheral region,
wherein a contact region is formed on a front surface of the semiconductor layer in the specific region,
wherein an outermost peripheral region of the outer peripheral region includes a first outermost peripheral region formed by the specific region, and a second outermost peripheral region in which a wiring electrically connected to the contact region is formed, and
wherein the first outermost peripheral region and the second outermost peripheral region each include one or more of the outer peripheral edges that are different from each other.
